(19) United States
(12) Patent Application Publication
(10) Pub. No.: US 2024/0306463 A1
(43) Pub. Date: Sep. 12, 2024

(54) DISPLAY DEVICE INCLUDING A HOLE AREA

(71) Applicant: SAMSUNG DISPLAY CO., LTD., Yongin-si (KR)

(72) Inventor: Woo Yong SUNG, Yongin-si (KR)

(21) Appl. No.: 18/521,919

(22) Filed: Nov. 28, 2023

(30) Foreign Application Priority Data
Mar. 6, 2023 (KR) 10-2023-0028917

(51) Int. Cl. H10K 59/35; G06F 3/044; G09G 3/3275; H10K 59/122; H10K 59/131; H10K 59/40; H10K 59/80

(52) U.S. Cl. CPC H10K 59/353; G06F 3/0445; G06F 3/0446; G09G 3/3275; H10K 59/122; H10K 59/131; H10K 59/40; H10K 59/8722

(57) ABSTRACT

A display device includes a substrate including a display area in which emission areas are arranged, a non-display area, a hole area, and a hole peripheral area. A light emitting element layer includes light emitting elements respectively corresponding to the emission areas. A through hole is disposed on the hole area and passes through at least the substrate. Sealing auxiliary units are disposed in the hole peripheral area and sequentially surround an edge of the hole area. A circuit layer includes pixel drivers corresponding to the emission areas. Data lines transmit data signals to the pixel drivers. Each of hole intersection data lines crossing the hole area and the hole peripheral area, among the data lines, include a hole bypass unit disposed in the hole peripheral area. The hole bypass units of the hole intersection data lines overlap the sealing auxiliary units.

This application claims priority under 35 U.S.C. § 119 to Korean Patent Application No. 10-2023-0028917, filed on Mar. 6, 2023, in the Korean Intellectual Property Office, the disclosure of which is incorporated by reference herein in its entirety.

### TECHNICAL FIELD

The present disclosure relates to a display device and, more specifically, to a display device including a hole area.

### DISCUSSION OF THE RELATED ART

A wide variety of display devices are currently in use. For example, display devices are applied to various electronic devices such as smartphones, digital cameras, notebook computers, navigation devices, and smart televisions.

The display devices may be flat panel display devices such as liquid crystal display devices, field emission display devices, and light emitting display devices. The light emitting display devices may include an organic light emitting display device including an organic light emitting element, an inorganic light emitting display device including an inorganic light emitting element such as an inorganic semiconductor, and a micro- or nano-light emitting display device including a micro- or nano-light emitting element.

An organic light emitting display device displays an image using a plurality of light emitting elements, each including a light emitting layer of an organic material. Since the organic light emitting display device implements image display using self-light emitting elements as described above, it may have a relatively higher performance than other display devices in terms of power consumption, response speed, luminous efficiency, luminance, and wide viewing angle.

### SUMMARY

A display device includes a substrate including a display area in which emission areas are arranged, a non-display area arranged around the display area, a hole area surrounded by the display area, and a hole peripheral area disposed between the hole area and the display area. A circuit layer is disposed on the substrate. A light emitting element layer is disposed on the circuit layer and includes light emitting elements respectively corresponding to the emission areas. A through hole is disposed on the hole area and passes through the substrate. Sealing auxiliary units are disposed in the hole peripheral area and surround an edge of the hole area. The circuit layer includes pixel drivers respectively corresponding to the emission areas. Data lines transmit data signals to the pixel drivers. Each of hole intersection data lines crossing the hole area and the hole peripheral area among the data lines include a hole bypass unit disposed in the hole peripheral area. The hole bypass units of the hole intersection data lines overlap the sealing auxiliary units.

The substrate may further include a sub-area protruding from the non-display area adjacent to one side of the edge of the display area. Each of the hole intersection data lines may further include a first hole adjacent unit extending between the one side of the edge of the display area and one side of the hole area, and a second hole adjacent unit extending between the other side of the edge of the display area and the other side of the hole area. The hole bypass unit may bypass the hole area along the edge of the hole area and may be connected between the first hole adjacent unit and the second hole adjacent unit.

Each of the sealing auxiliary units may include metal layers stacked in an undercut structure.

The circuit layer may further include a via layer covering the data lines and an auxiliary insulating layer disposed in the hole peripheral area, covering the via layer, and formed of an inorganic insulating material layer. The light emitting element layer may be disposed on the via layer. The sealing auxiliary units may be disposed on the auxiliary insulating layer.

The light emitting element layer may include anode electrodes respectively disposed in the emission areas. A bank buffer layer may be disposed in a non-emission area which is between the emission areas and covering the edge of each of the anode electrodes. A cathode connection electrode may be disposed on the bank buffer layer and may include metal layers stacked in an undercut structure. A pixel defining layer may be disposed on the cathode connection electrode. First common layers may be respectively disposed on the anode electrodes. Light emitting layers may be respectively disposed on the first common layers. A second common layer may be disposed on the pixel defining layer and the light emitting layers. A cathode electrode may be disposed on the second common layer. The second common layer and the cathode electrode may be separated by the undercut structure of the cathode connection electrode and the undercut structure of each of the sealing auxiliary units. The cathode electrode may be in contact with the side surface of the cathode connection electrode to be electrically connected to the cathode connection electrode in each emission area. The first common layer, the light emitting layer and the second common layer may be provided in a stacked structure between the anode electrode and the cathode electrode in each emission area.

Each of the cathode connection electrode and the sealing auxiliary units may include a main layer, a bottom layer disposed under the main layer, and a top layer disposed on the main layer and having an edge protruding to a greater extent than the main layer.

The main layer may include aluminum (Al) or copper (Cu). The top layer may include titanium (Ti) or molybdenum (Mo).

The bottom layer may include titanium (Ti) or molybdenum (Mo).

The bottom layer may include an inorganic insulating material that is not present within the auxiliary insulating layer.

The display device may further include a first sealing layer disposed on the circuit layer, covering the light emitting element layer, and including an inorganic insulating material. The first sealing layer may be in contact with the auxiliary insulating layer in the hole peripheral area.

The side surface of the main layer may include a common bonding portion in contact with the second common layer, a cathode bonding portion in contact with the cathode electrode, and a scaling bonding portion in contact with the first sealing layer.

The display device may further include a second sealing layer disposed on the first sealing layer, covering the light emitting element layer and the sealing auxiliary units and may include an organic insulating material. A third sealing layer may be disposed on the first sealing layer, covering the second sealing layer, and including an inorganic insulating material. The third sealing layer may be in contact with the first sealing layer in the hole peripheral area.

The auxiliary insulating layer may cover the via layer.

The display device may further include a touch sensor layer disposed on the first sealing layer. The touch sensor layer may include a first additional overcoat layer disposed on the first sealing layer in each of the emission areas, a first sensor electrode layer disposed on the first scaling layer in the non-emission area, a first sensor insulating layer disposed on the first sensor electrode layer and the first additional overcoat layer, a second sensor electrode layer disposed on the first sensor insulating layer, an overcoat layer covering the second sensor electrode layer, a second sensor insulating layer covering the overcoat layer, and a second additional overcoat layer covering the second sensor insulating layer. The first additional overcoat layer may be disposed between the sealing auxiliary units in the hole peripheral area. The first sensor insulating layer may be in contact with the first sealing layer on each of the cathode connection electrode and the sealing auxiliary units.

The display device may further include a touch sensor layer disposed on the first sealing layer. The touch sensor layer may include a first additional overcoat layer disposed on the first sealing layer in the display area, an additional sensor insulating layer disposed on the first additional overcoat layer, a first sensor electrode layer disposed on the additional sensor insulating layer, a first sensor insulating layer disposed on the additional sensor insulating layer and the first sensor electrode layer, a second sensor electrode layer disposed on the first sensor insulating layer, an overcoat layer covering the second sensor electrode layer, and a second sensor insulating layer disposed on the overcoat layer. The additional sensor insulating layer may be in contact with the first sealing layer in a portion adjacent to the edge of the hole area among the hole peripheral area.

A display device includes a substrate including a display area in which emission areas are arranged, a non-display area arranged around the display area, a hole area surrounded by the display area, and a hole peripheral area between the hole area and the display area. A circuit layer is disposed on the substrate. A light emitting element layer is disposed on the circuit layer and includes light emitting elements respectively corresponding to the emission areas. A through hole is disposed on the hole area and passes through the substrate. Sealing auxiliary units are disposed in the hole peripheral area, surrounding the edge of the hole area, and including metal layers stacked in an undercut structure. The circuit layer includes pixel drivers respectively corresponding to the emission areas, data lines transmitting data signals to the pixel drivers, a via layer covering the data lines, and an auxiliary insulating layer disposed in the hole peripheral area, covering the via layer, and including an inorganic insulating material. The data lines include hole intersection data lines crossing the hole area and the hole peripheral area. Each of the hole intersection data lines includes a hole bypass unit disposed in the hole peripheral area. The sealing auxiliary units are disposed on the auxiliary insulating layer and overlap the hole bypass units of the hole intersection data lines.

The auxiliary insulating layer may cover the via layer.

The substrate may further include a sub-area protruding from the non-display area adjacent to one side of the edge of the display area. Each of the hole intersection data lines may further include a first hole adjacent unit extending between the one side of the edge of the display area and one side of the hole area, and a second hole adjacent unit extending between the other side of the edge of the display area and the other side of the hole area. The hole bypass unit may bypasses the hole area along the edge of the hole area and may be connected between the first hole adjacent unit and the second hole adjacent unit.

The light emitting element layer may include anode electrodes disposed on the via layer in each of the emission areas, a bank buffer layer disposed in a non-emission area which between the emission areas and covering the edge of each of the anode electrodes, a cathode connection electrode disposed on the bank buffer layer and including metal layers stacked in an undercut structure, a pixel defining layer disposed on the cathode connection electrode layer, first common layers respectively disposed on the anode electrodes, light emitting layers respectively disposed on the first common layers, a second common layer disposed on the pixel defining layer and the light emitting layers, and a cathode electrode disposed on the second common layer. The second common layer and the cathode electrode may be separated by the undercut structure of the cathode connection electrode and the undercut structure of each of the sealing auxiliary units. The cathode electrode may be in contact with the side surface of the cathode connection electrode and electrically connected to the cathode connection electrode in each emission area. The first common layer, the light emitting layer and the second common layer may be disposed in a stacked structure between the anode electrode and the cathode electrode in each emission area.

Each of the cathode connection electrode and the sealing auxiliary units may include a main layer, a bottom layer disposed under the main layer, and a top layer disposed on the main layer and having an edge protruding to a greater extent than the main layer. The main layer may include aluminum (Al) or copper (Cu). The top layer may include titanium (Ti) or molybdenum (Mo).

The bottom layer may include titanium (Ti) or molybdenum (Mo).

The bottom layer may include inorganic insulating material that is different from the auxiliary insulating layer.

The display device may further include a first sealing layer disposed on the circuit layer, covering the light emitting element layer, and including an inorganic insulating material. The first scaling layer may be in contact with the auxiliary insulating layer in the hole peripheral area. The side surface of the main layer may include a common bonding portion in contact with the second common layer, a cathode bonding portion in contact with the cathode electrode, and a sealing bonding portion in contact with the first sealing layer.

The display device may further include a touch sensor layer disposed on the first scaling layer. The touch sensor layer may include a first additional overcoat layer disposed on the first scaling layer in each of the emission areas. A first sensor electrode layer may be disposed on the first sealing layer in the non-emission area. A first sensor insulating layer may be disposed on the first sensor electrode layer and the first additional overcoat layer. A second sensor electrode layer may be disposed on the first sensor insulating layer. An overcoat layer may cover the second sensor electrode layer. A second sensor insulating layer may covers the overcoat layer. A second additional overcoat layer may cover the second sensor insulating layer. The first additional overcoat layer may be disposed between the sealing auxiliary units in the hole peripheral area. The first sensor insulating layer may be in contact with the first sealing layer on each of the cathode connection electrode and the sealing auxiliary units.

The display device may further include a touch sensor layer disposed on the first scaling layer. The touch sensor layer may include a first additional overcoat layer evenly disposed on the first sealing layer in the display area. An additional sensor insulating layer may be disposed on the first additional overcoat layer. A first sensor electrode layer may be disposed on the additional sensor insulating layer. A first sensor insulating layer may be disposed on the additional sensor insulating layer and the first sensor electrode layer. A second sensor electrode layer may be disposed on the first sensor insulating layer. An overcoat layer may cover the second sensor electrode layer. A second sensor insulating layer may be disposed on the overcoat layer. The additional sensor insulating layer may be in contact with the first sealing layer in a portion adjacent to the edge of the hole area among the hole peripheral area.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a plan view of the display device of FIG. 1;

FIG. 3 is a cross-sectional view taken along line A-A′ of FIG. 2;

FIG. 4 is a plan view of a main area and a sub-area of the display device of FIG. 1;

FIG. 5 is a layout view illustrating an example of emission areas arranged in portion B of FIG. 4;

FIG. 6 is a plan view of an example of a sensor electrode layer of FIG. 3;

FIG. 7 is an enlarged view illustrating portion D of FIG. 6;

FIG. 8 is a cross-sectional view taken along line E-E′ of FIG. 7 according to an embodiment;

FIG. 9 is an equivalent circuit diagram of one pixel driver among a circuit layer of FIG. 3;

FIG. 10 is a plan view of two adjacent pixel drivers among the circuit layer of FIG. 3;

FIG. 11 is a plan view of a semiconductor layer and a first conductive layer among a plan view of FIG. 10;

FIG. 12 is a plan view of a semiconductor layer, a first conductive layer, and a second conductive layer among a plan view of FIG. 10;

FIG. 13 is a plan view of a third conductive layer among a plan view of FIG. 10;

FIG. 14 is a cross-sectional view taken along line F-F′ of FIG. 10 according to an embodiment;

FIG. 15 is a layout view illustrating an example of data lines and first power lines of a circuit layer disposed in portion C of FIG. 4;

FIG. 16 is a cross-sectional view taken along line G-G′ of FIG. 15 according to an embodiment;

FIG. 17 is an enlarged view illustrating an example of portion H of FIG. 15;

FIG. 18 is an enlarged view illustrating another example of portion H of FIG. 15;

FIG. 19 is a cross-sectional view taken along line G-G′ of FIG. 15 according to an embodiment;

FIG. 20 is a cross-sectional view taken along line F-F′ of FIG. 10 according to an embodiment;

FIG. 21 is a cross-sectional view taken along line E-E′ of FIG. 7 according to an embodiment;

FIG. 22 is a cross-sectional view taken along line G-G′ of FIG. 15 according to an embodiment;

FIG. 23 is a cross-sectional view taken along line E-E′ of FIG. 7 according to an embodiment; and

FIG. 24 is a cross-sectional view taken along line G-G′ of FIG. 15 according to an embodiment.

### DETAILED DESCRIPTION

Embodiments of the present disclosure will now be described more fully hereinafter with reference to the accompanying drawings. The embodiments may, however, be provided in different forms and should not necessarily be construed as limiting. The same reference numbers may indicate the same components throughout the present disclosure and the figures.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not necessarily be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

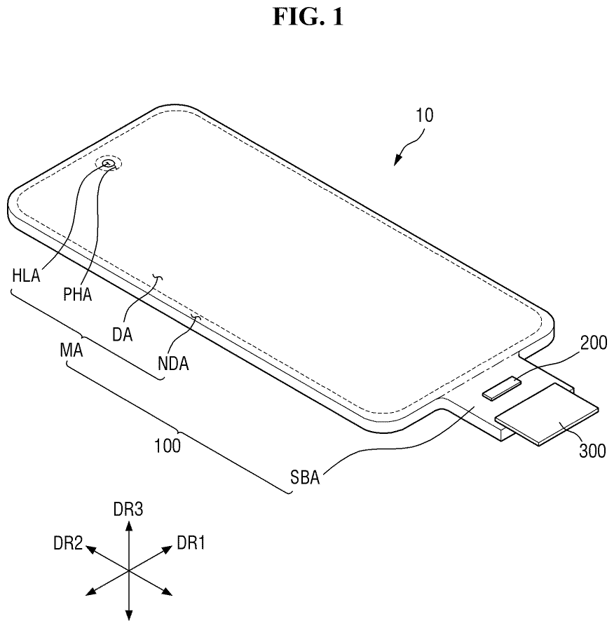

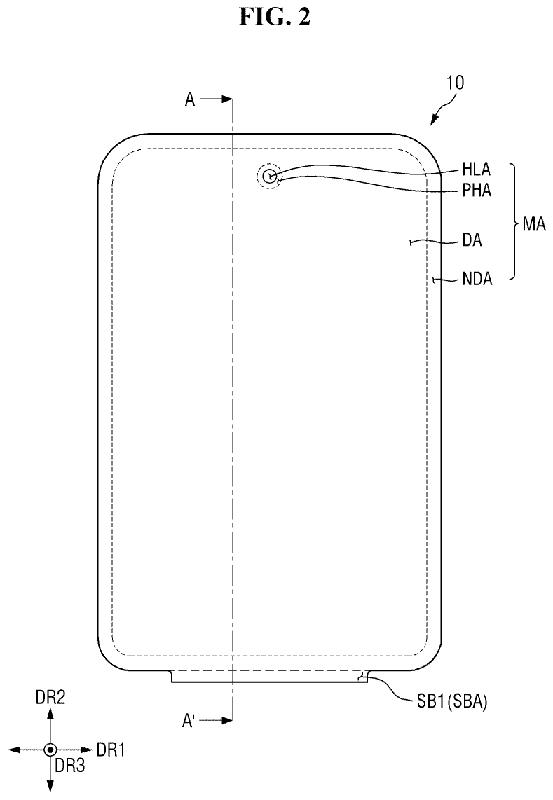

FIG. 1 is a perspective view of a display device according to an embodiment. FIG. 2 is a plan view of the display device of FIG. 1.

Referring to FIGS. 1 and 2, the display device 10 is a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and Internet of things (IoT) devices.

The display device 10 may be a light emitting display device such as an organic light emitting display device using an organic light emitting diode, a quantum dot light emitting display device including a quantum dot light emitting layer, an inorganic light emitting display device including an inorganic semiconductor, or a micro- or nano-light emitting display device using a micro- or nano-light emitting diode. A case where the display device 10 is an organic light emitting display device will be mainly described below, but the present disclosure may be also applicable to display devices including an organic insulating material, an organic light emitting material, and a metal material.

The display device 10 may be formed flat, but the present disclosure is not necessarily limited thereto. For example, the display device 10 may include curved portions formed at left and right ends and having a constant or varying curvature. In addition, the display device 10 may be formed to be flexible so that it can be curved, bent, folded, or rolled.

The display device 10 may include a display panel 100, a display driving circuit 200, and a circuit board 300.

The display panel 100 may include a main area MA disposed in a display surface in which an image is displayed and a sub-area SBA protruding from a side of the main area MA.

The main area MA includes a display area DA in which light for displaying an image is emitted, a non-display area NDA disposed around the display area DA, a hole area HLA surrounded by the display area DA, and a hole peripheral area PHA between the hole area HLA and the display area DA.

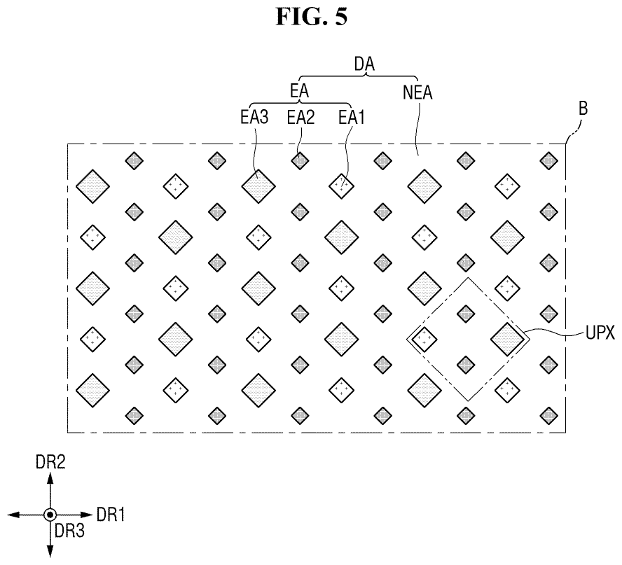

Emission areas (EA of FIG. 5) are arranged in the display area DA.

For example, the display device 10 includes the display area DA in which the emission areas (EA of FIG. 5) are arranged, the non-display area NDA arranged around the display area DA, the hole area HLA surrounded by the display area DA, and the hole peripheral area PHA disposed between the hole area HLA and the display area DA.

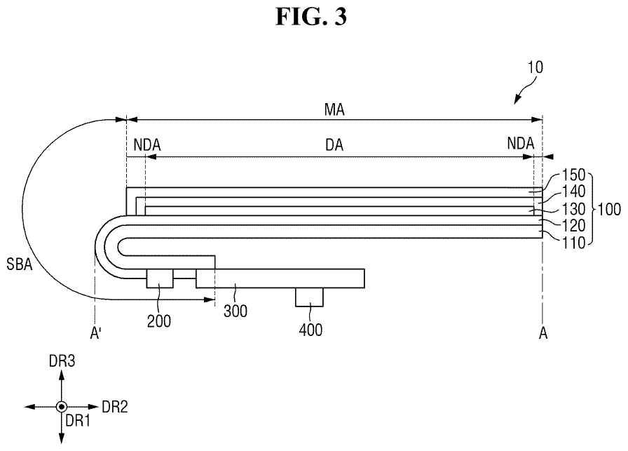

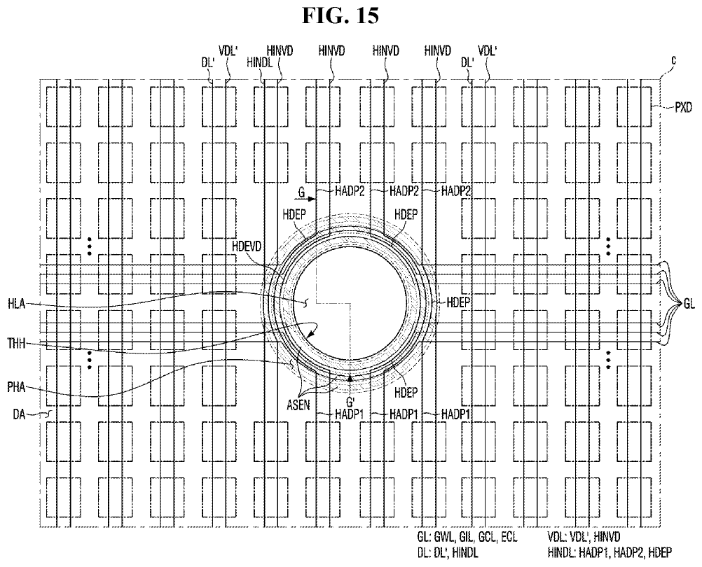

The display device 10 may further include a through hole (THH of FIG. 15) disposed in the hole area HLA. The through hole THH may pass through at least a substrate (110 of FIG. 3) of the display panel 100. For example, the through hole THH may pass through the entire display panel 100.

The through hole THH may overlap at least a portion of a functional module disposed outside the display panel 100 and may be provided as a path for inputting sensing information of the functional module or a path for outputting sound of the functional module.

For one example, the functional module may be disposed under the display panel 100 to overlap the through hole THH or within the through hole THH.

For example, the functional module may include a camera module for capturing or recognizing an image corresponding to the front of the display device 10, a face recognition sensor module for detecting a user's face, a pupil recognition sensor module for detecting a user's eyes, an acceleration sensor module and a geomagnetic sensor module for judging the movement of the display device 10, a proximity sensor module and an infrared sensor module for detecting proximity to the front of the display device 10, an illuminance sensor module for measuring an external brightness level, etc.

The sub-area SBA may be an area protruding from a side of the non-display area NDA of the main area MA in a second direction DR2.

The display driving circuit 200 may be mounted on the sub-area SBA, and the circuit board 300 may be attached to the sub-area SBA.

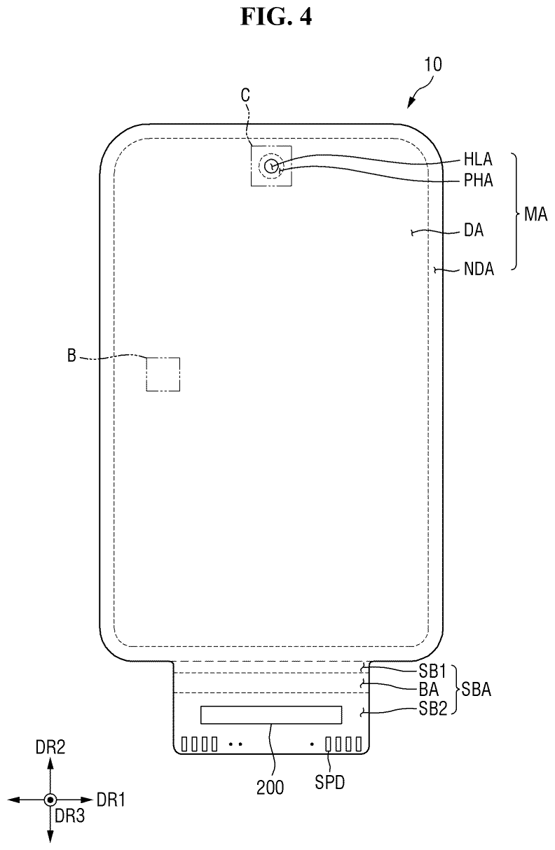

The display driving circuit 200 may be provided as an integrated circuit and mounted on a second sub-area SB2 (see FIG. 4) by a chip on glass (COG) method, a chip on plastic (COP) method, or an ultrasonic bonding method. However, the present disclosure is not necessarily limited thereto. For example, the display driving circuit 200 may also be mounted on the circuit board 300 by a chip on film (COF) method or may be embedded as a part of the display panel 100.

The circuit board 300 may be attached to an edge of the sub-area SBA that is relatively far from the main area MA by using an anisotropic conductive film or a low-resistance, high-reliability material such as SAP.

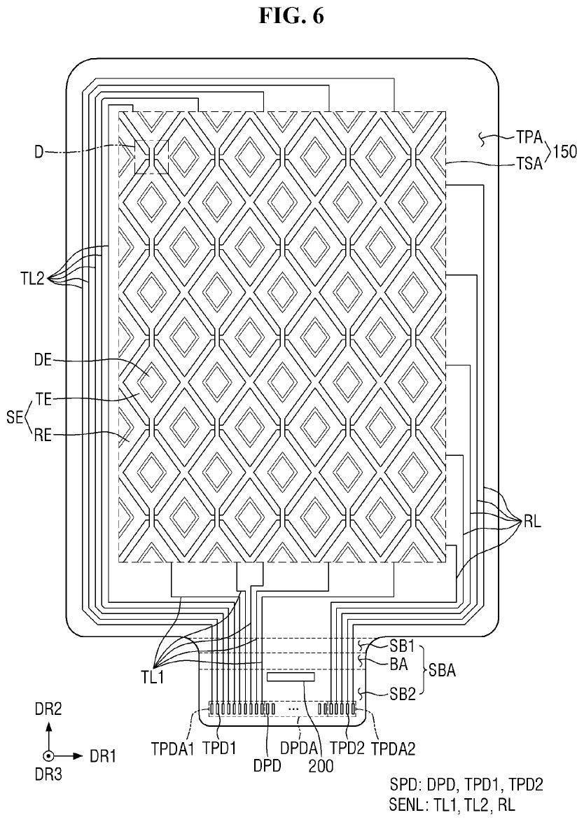

The circuit board 300 may supply digital video data, timing signals, and driving voltages to the display driving circuit 200 or the pixel driving units (PXD of FIG. 6) of the circuit layer (120 of FIG. 3).

The circuit board 300 may be a flexible printed circuit board, a printed circuit board, or a flexible film such as a chip on film.

As illustrated in FIG. 2, a portion of the sub-area SBA may be bent. Accordingly, the display driving circuit 200 disposed in the sub-area SBA and the circuit board 300 attached to the sub-area SBA may be disposed on the rear surface of the display panel 100.

FIG. 3 is a cross-sectional view taken along line A-A′ of FIG. 2.

Referring to FIG. 3, the display panel 100 of the display device 10, according to an embodiment, includes the substrate 110, a circuit layer 120 disposed on the substrate 110, and a light emitting element layer 130 disposed on the circuit layer 120.

In addition, the display panel 100 of the display device 10, according to an embodiment, may further include a sealing layer 140 disposed on the light emitting element layer 130, and a touch sensor layer 150 disposed on the sealing layer 140.

The substrate 110 includes the display area DA in which the emission areas EA are arranged, the non-display area NDA disposed around the display area DA, the hole area HLA surrounded by the display area DA, and the hole peripheral area PHA between the hole area HLA and the display area DA.

The substrate 110 may include the main area MA and the sub-area SBA. The main area MA of the substrate 110 includes the display area DA, the non-display area NDA, the hole area HLA, and the hole peripheral area PHA.

The substrate 110 may include an insulating material such as polymer resin. For example, the substrate 110 may include polyimide. The substrate 110 may be a flexible substrate that can be bent, folded, or rolled.

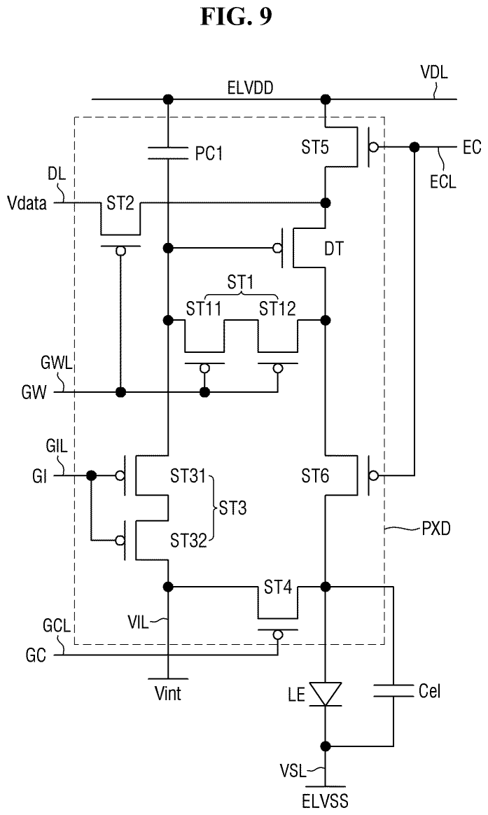

The circuit layer 120 includes pixel driving units (PXD of FIG. 9) respectively corresponding to emission areas EA, and data lines (DL of FIG. 9) transmitting data signals (Vdata of FIG. 9) to the pixel driving units PXD.

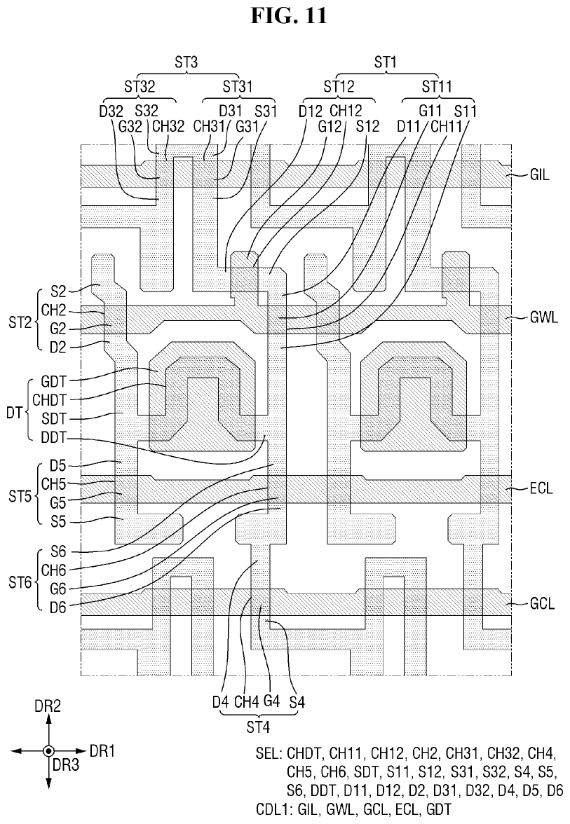

The light emitting element layer 130 may be disposed on the circuit layer 120 in the display area DA. The light emitting element layer 130 includes light emitting elements (LE of FIGS. 6 and 11) respectively corresponding to the emission areas EA. The light emitting elements LE of the light emitting element layer 130 may be electrically connected to the pixel drivers PXD of the circuit layer 120, respectively.

In addition, the display device 10 further includes the through hole THH disposed in the hole area HLA and penetrating at least the substrate 110 and a sealing auxiliary unit (ASEN of FIG. 15) sequentially surrounding the edge of the hole area HLA.

For example, the through hole THH may penetrate the display panel 100 of the hole area HLA.

The sealing layer 140 may be disposed in the main area MA on the circuit layer 120 and cover the light emitting element layer 130. A portion of the sealing layer 140 including an inorganic insulating material may be in contact with the circuit layer 120 in the non-display area NDA.

The sealing layer 140 is designed to protect the light emitting element layer 130 from permeation of oxygen or moisture.

The touch sensor layer 150 may be disposed on the sealing layer 140 in the main area MA. The touch sensor layer 150 may include touch electrodes for sensing a touch of a person or an object.

The display device 10 may further include a cover window disposed on the touch sensor layer 150. The cover window may be attached onto the touch sensor layer 150 by a transparent adhesive member such as an optically clear adhesive (OCA) film or an optically clear resin (OCR). The cover window may be an inorganic material such as glass or may be an organic material such as plastic or a polymer material. The cover window may protect the touch sensor layer 150, the sealing layer 140, the light emitting element layer 130, and the circuit layer 120 from electrical and physical impact on a display surface.

In addition, the display device 10 may further include an anti-reflection member disposed between the touch sensor layer 150 and the cover window. The anti-reflection member may be a polarizing film or a color filter. The anti-reflection member may block external light reflected by the touch sensor layer 150, the sealing layer 140, the light emitting element layer 130, the circuit layer 120, and interfaces between them, thereby preventing a reduction in visibility of an image of the display device 10.

The display device 10 may further include a touch driving circuit 400 for driving the touch sensor layer 150.

The touch driving circuit 400 may be provided as an integrated circuit. The touch driving circuit 400 may be mounted on the circuit board 300 and thus electrically connected to the touch sensor layer 150.

Alternatively, like the display driving circuit 200, the touch driving circuit 400 may be mounted on the sub-area SBA of the substrate 110.

The touch driving circuit 400 may transmit a touch driving signal to a plurality of driving electrodes included in the touch sensor layer 150, receive touch sensing signals of a plurality of touch nodes through a plurality of sensing electrodes, respectively, and detect amounts of charge change in mutual capacitance based on the touch sensing signals.

For example, the touch driving circuit 400 may determine whether a user's touch or proximity has occurred based on the touch sensing signal of each of the touch nodes. The user's touch indicates that an object such as the user's finger or a pen/stylus directly touches a front surface of the display device 10. The user's proximity indicates that an object such as the user's finger or a pen/stylus hovers above the front surface of the display device 10.

FIG. 4 is a plan view of the main area MA and the sub-area SBA of the display device 10 of FIG. 1.

The display device 10 may include the main area MA which includes the display area DA emitting light for image display and the sub-area SBA which protrudes from a side of the main area MA.

The main area MA may include the display area DA in which the emission areas (EA of FIG. 5) are arranged, the non-display area NDA disposed around the display area DA, the hole area HLA surrounded by the display area DA, and the hole peripheral area PHA between the hole area HLA and the display area DA.

The display area DA may be shaped like a rectangle having a pair of short sides extending in a first direction DR1 and a pair of long sides extending in the second direction DR2 intersecting the first direction DR1. Each corner where a short side extending in the first direction DR1 meets a long side extending in the second direction DR2 may be rounded with a predetermined curvature or may be right-angled. The planar shape of the display area DA is not necessarily limited to a quadrilateral shape but may also be another polygonal shape, a circular shape, or an oval shape.

The display area DA may occupy most of the main area MA. The display area DA may be disposed in a center of the main area MA.

The non-display area NDA may neighbor the display area DA and may be disposed outside edges of the display area DA. For example, the non-display area NDA may be an area outside the display area DA. The non-display area NDA may at least partially surround the display area DA. The non-display area NDA may be an edge area of the main area MA.

The sub-area SBA may protrude from a side of the main area MA in the second direction DR2. A length of the sub-area SBA in the first direction DR1 may be smaller than a length of the main area MA in the second direction DR2. The length of the sub-area SBA in the first direction DR1 may be smaller than a length of the main area MA in the first direction DR1 or may be substantially the same as the length of the main area MA in the first direction DR1.

The sub-area SBA may include a bending area BA which is transformed into a bent shape and a first sub-area SB1 and the second sub-area SB2 which contact both sides of the bending area BA.

The first sub-area SB1 is an area disposed between the main area MA and the bending area BA. A side of the first sub-area SB1 may contact the non-display area NDA of the main area MA, and the other side of the first sub-area SB1 may contact the bending area BA.

The second sub-area SB2 is an area spaced apart from the main area MA with the bending area BA interposed between them and an area disposed on the rear surface of the display panel 100 due to the bending area BA transformed into a bent shape. For example, the second sub-area SB2 may overlap the main area MA in a thickness direction DR3 of the display panel 100 due to the bending area BA transformed into a bent shape.

A side of the second sub-area SB2 may contact the bending area BA. The other side of the second sub-area SB2 may include a portion of an edge of the substrate (110 of FIG. 3) and contact the circuit board (300 of FIG. 3).

Signal pads SPD and the display driving circuit 200 may be disposed in the second sub-area SB2.

The display driving circuit 200 may generate signals and voltages for driving the pixel drivers PD of the display area DA.

The circuit board 300 may be attached to the signal pads SPD of the second sub-area SB2 and electrically connected to the signal pads SPD.

The hole area HLA may be disposed to be spaced far apart from the sub-area SBA and adjacent to an edge of the display area DA.

Although one circular hole area HLA is illustrated in FIGS. 1, 2 and 4, the shape of the hole area HLA according to an embodiment is not necessarily limited to a circular shape. The hole area HLA may also be provided in a polygonal shape such as a triangle or a square or in an oval shape. The display device 10 according to the embodiment may also include two or more hole areas HLA.

The hole peripheral area PHA is an area between the hole area HLA and the display area DA. For example, the hole peripheral area PHA is an area outside the hole area HLA and may at least partially surround the hole area HLA.

The hole peripheral area PHA may have a shape similar to that of the hole area HLA. However, the present disclosure is not necessarily limited thereto, and the hole peripheral area PHA, according to an embodiment, may also have a shape different from that of the hole area HLA.

FIG. 5 is a layout view illustrating an example of the emission areas EA arranged in portion B of FIG. 4.

Referring to FIG. 5, the display area DA may include the emission areas EA and a non-emission area NEA disposed between the emission areas EA.

Each of the emission areas EA may be a unit that emits light in a wavelength band corresponding to one of two or more different colors with a luminance corresponding to an image signal.

For example, the emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

For example, the first color may be red in a wavelength band of approximately 600 to approximately 750 nm, the second color may be green in a wavelength band of approximately 480 to approximately 560 nm, and the third color may be blue in a wavelength band of approximately 370 to approximately 460 nm. However, this is an example, and the wavelength bands of the first color, the second color and the third color according to an embodiment of the present specification are not necessarily limited thereto.

Since the emission areas EA include the first emission areas EA1, the second emission areas EA2 and the third emission areas EA3, unit pixels UPX, each including a combination of one or more first emission areas EA1, one or more second emission areas EA2 and one or more third emission areas EA3 adjacent to each other among the emission areas EA may be provided.

Each of the unit pixels UPX may be a unit for displaying various colors including white. For example, light of various colors displayed in each unit pixel UPX may be realized as a mixture of light emitted from two or more emission areas EA included in each unit pixel UPX.

For example, as illustrated in FIG. 5, the first emission areas EA1 and the third emission areas EA3 may be alternately arranged in the first direction DR1 and the second direction DR2. In addition, the second emission areas EA2 may be arranged side by side in the first direction DR1 and the second direction DR2. The second emission areas EA2 may respectively neighbor the first emission areas EA1 and the third emission areas EA3 in the first direction DR1 or the second direction DR2.

In this case, each of the unit pixels UPX may include one first emission area EA1 and one third emission area EA3 adjacent to each other in the first direction DR1 and two second emission areas EA2 adjacent in the diagonal directions of the first emission area EA1 and third emission area EA3. However, this is an example, and the arrangement pattern of the emission areas EA and the components of the unit pixel UPX according to an embodiment are not necessarily limited to those illustrated in FIG. 5.

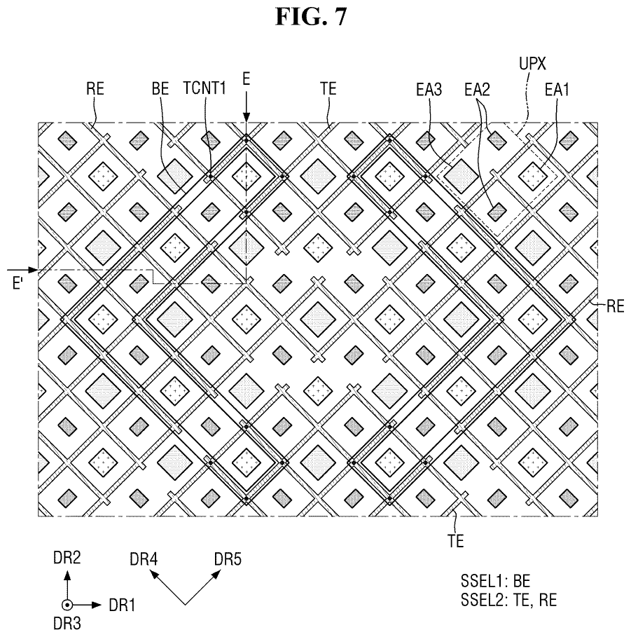

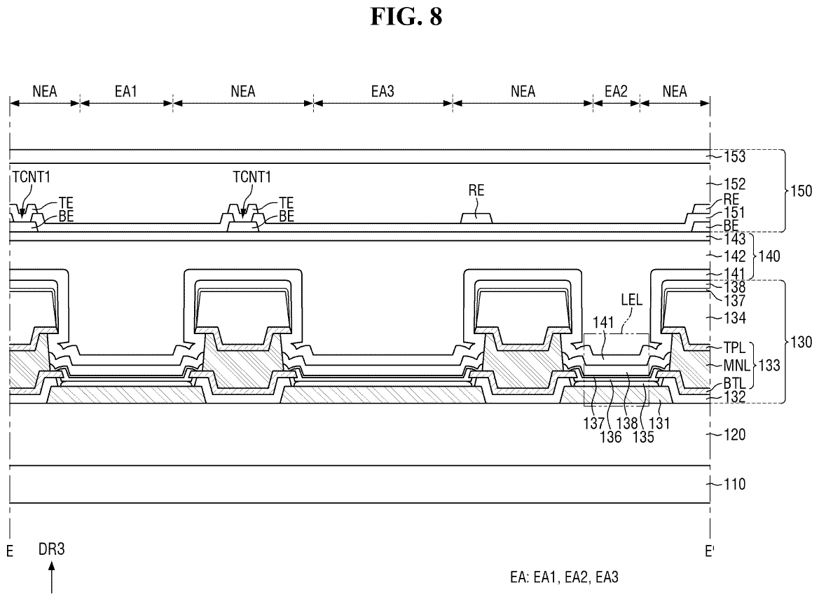

FIG. 6 is a plan view of an example of a sensor electrode layer of FIG. 3. FIG. 7 is an enlarged view illustrating portion D of FIG. 6. FIG. 8 is a cross-sectional view taken along line E-E′ of FIG. 7 according to an embodiment.

FIG. 6 shows a capacitive touch sensor layer 150. In this case, the touch driving circuit 400 may detect a touch based on a change in capacitance. However, FIG. 6 is an example for easy description, and the touch sensor layer 150 according to an embodiment is not necessarily limited to the illustration in FIG. 6.

For ease of description, FIG. 6 illustrates some of the elements of the touch sensor layer 150.

Referring to FIG. 6, the touch sensor layer 150 may be disposed in the main area MA. The touch sensor layer 150 may include a touch sensing area TSA for sensing a user's touch and a touch peripheral area TPA around the touch sensing area TSA.

The touch sensing area TSA may be wider than the display area DA and may be similar to the display area DA. Accordingly, the touch peripheral area TPA disposed around the touch sensing area TSA may be similar to the non-display area NDA disposed around the display area DA.

For example, the touch sensing area TSA may overlap the display area DA and edges of the non-display area NDA adjoining the display area DA. In this case, the touch peripheral area TPA may overlap the remaining portion of the non-display area NDA which does not correspond to the touch sensing area TSA.

The touch sensor layer 150 may include sensor electrodes SE and dummy electrodes DE which are arranged in a matrix in the touch sensing area TSA and generate mutual capacitance and sensor lines SENL which are disposed in the touch peripheral area TPA.

The sensor electrodes SE may include touch driving electrodes TE to which driving signals are transmitted and receiving electrodes RE for sensing voltages charged in mutual capacitance with the touch driving electrodes TE.

The sensor lines SENL may include first driving lines TL1, second driving lines TL2, and sensing lines RL.

Each of the first and second driving lines TL1 and TL2 may be electrically connected to two or more touch driving electrodes TE connected in the second direction DR2 among the touch driving electrodes TE.

The first driving lines TL1 may extend from a portion of the touch peripheral area TPA between one side of the touch sensing area TSA in the second direction DR2 and a sub-area SBA to the sub-area SBA.

The second driving lines TL2 may extend from a portion of the touch peripheral area TPA in contact with the other side of the touch sensing area TSA in the second direction DR2 to the sub-area SBA via a portion in contact with one side of the touch sensing area TSA in the first direction DR1.

Each of the sensing lines RL may be electrically connected to two or more receiving electrodes RE connected in the first direction DR1 among the receiving electrodes RE.

The receiving electrodes RE may be arranged side by side in the first direction DR1. The receiving electrodes RE neighboring each other in the first direction DR1 may be electrically connected to each other through a protruding portion in the first direction DR1.

The touch driving electrodes TE may be arranged side by side in the second direction DR2. The touch driving electrodes TE neighboring each other in the second direction DR2 may be electrically connected to each other through bridge electrodes (BE of FIG. 7) in the second direction DR2.

Each of the touch driving electrodes TE and the receiving electrodes RE may at least partially surround a dummy electrode DE disposed in its center.

Each of the dummy electrodes DE may be spaced apart from a touch driving electrode TE or a receiving electrode RE surrounding the dummy electrode DE. The dummy electrodes DE may be kept in a floating state.

Although the touch driving electrodes TE, the receiving electrodes RE, and the dummy electrodes DE have a rhombic planar shape in FIG. 6, an embodiment is not necessarily limited to the illustration in FIG. 6. For example, the touch driving electrode TE, the receiving electrodes RE, and the dummy electrodes DE may also have a quadrilateral shape other than a rhombus shape, a polygonal shape other than a quadrilateral shape, a circular shape, or an oval shape in a plan view.

The display panel 100 of the display device 10, according to the embodiment, may include the signal pads SPD disposed in the second sub-area SB2 and connected to the circuit board 300.

The signal pads SPD may include display signal pads DPD for transmitting and receiving signals for driving the circuit layer 120 and touch signal pads TPD1 and TPD2 for transmitting and receiving signals for driving the touch sensor layer 150.

For example, the second sub-area SB2 may include a display pad area DPDA adjacent to the display driving circuit 200 and a first touch pad area TPDA1 and a second touch pad area TPDA2 disposed on both sides of the display pad area DPDA.

The display pads DPD for transmitting and receiving signals to and from the circuit layer 120 or the display driving circuit 200 may be disposed in the display pad area DPDA.

First touch pads TPD1 electrically connected to the first driving lines TL1 and the second driving lines TL2, respectively, may be disposed in the first touch pad area TPDA1.

Second touch pads TPD2 electrically connected to the sensing lines RL, respectively, may be disposed in the second touch pad area TPDA2.

Referring to FIG. 7, the bridge electrodes BE may be provided as a first sensor electrode layer SSEL1, and the touch driving electrodes TE and the receiving electrodes RE may be provided as a second sensor electrode layer SSEL2.

The touch driving electrodes TE and the receiving electrodes RE may be spaced apart from each other.

Although the bridge electrodes BE bent at least once are illustrated in FIG. 7, the shape of the bridge electrodes BE according to an embodiment is not necessarily limited to that illustrated in FIG. 7.

The touch driving electrodes TE neighboring each other in the second direction DR2 may be electrically connected to each other through two or more bridge electrodes BE. In this case, the reliability of electrical connection between the touch driving electrodes TE can be increased.

Although two bridge electrodes BE parallel to each other are disposed between the touch driving electrodes TE neighboring each other in the second direction DR2 in FIG. 7, an embodiment is not necessarily limited to the illustration in FIG. 7.

The bridge electrodes BE may be electrically connected to the touch driving electrodes TE through touch contact holes TCNT1.

The touch driving electrodes TE, the receiving electrodes RE, and the bridge electrodes BE may have a mesh or net structure in a plan view. The dummy electrodes DE may also have a mesh or net structure in a plan view. In this case, a width of a portion of each of the emission areas EA which overlaps a touch driving electrode TE, a receiving electrode RE, a dummy electrode DE, and a bridge electrode BE may be reduced. Accordingly, a decrease in light emission efficiency due to the touch driving electrodes TE, the receiving electrodes RE, the dummy electrodes DE, and the bridge electrodes BE can be reduced.

The emission areas EA may include the first emission areas EA1 emitting light of the first color, the second emission areas EA2 emitting light of the second color in a wavelength band lower than that of the first color, and the third emission areas EA3 emitting light of the third color in a wavelength band lower than that of the second color. For example, the first color, second color, and third color may be red, green, and blue, respectively.

The first emission areas EA1 and the third emission areas EA3 may be alternately arranged in the first direction DR1 and the second direction DR2.

The second emission areas EA2 may respectively neighbor the first emission areas EA1 and the third emission areas EA3 in a fourth direction DR4 and a fifth direction DR5. The second emission areas EA2 may be arranged side by side in the first direction DR1 and the second direction DR2.

The fourth direction DR4 is a diagonal direction between the first direction DR1 and the second direction DR2. The fifth direction DR5 is a direction orthogonal to the fourth direction DR4. For example, the fourth direction DR4 may be a direction inclined by 45 degrees to the first direction DR1.

Although each of the emission areas EA has a rhombic or rectangular planar shape in FIG. 7, the planar shape of each of the emission areas EA, according to an embodiment, is not necessarily limited to that illustrated in FIG. 7. For example, each of the emission areas EA may also have a polygonal shape other than a quadrilateral shape, a circular shape, or an oval shape in a plan view.

As illustrated in FIG. 7, when the first color of the first emission areas EA1, the second color of the second emission areas EA2, and the third color of the third emission areas EA3 are red, green, and blue, respectively, the third emission areas EA3 may be wider than the first emission areas EA1, and the second emission areas EA2 may be narrower than the first emission areas EA1. However, this is an example, and the width of each of the emission areas EA is not necessarily limited to that illustrated in FIG. 7.

Referring to FIG. 8, the display panel 100 of the display device 10, according to the embodiment, may include the substrate 110, the circuit layer 120 on the substrate 110, the light emitting element layer 130 on the circuit layer 120, the sealing layer 140 on the light emitting element layer 130, and the touch sensor layer 150 on the sealing layer 140.

The substrate 110 may include a material having a flexible characteristic capable of bending, folding, rolling, or the like.

The substrate 110 may include an insulating material such as polymer resin. For example, the substrate 110 may include polyimide.

The circuit layer 120 may include the pixel drivers PXD respectively corresponding to the emission areas EA.

The light emitting element layer 130 includes light emitting elements LEL respectively corresponding to the emission areas EA.

Each of the light emitting elements LEL may have a structure which includes the anode electrode 131 and the cathode electrode 138 facing each other and a first common layer 135, a light emitting layer 136, and a second common layer 137 sequentially stacked between the anode electrode 131 and the cathode electrode 138 and formed of organic materials.

The anode electrode 131 may be disposed in each of the emission areas EA and may be electrically connected to a pixel driver PXD of the circuit layer 120. The anode electrode 131 may be referred to as a pixel electrode.

The anode 131 may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The first common layer 135 on the anode electrode 131 may be disposed in each of the emission areas EA. The first common layer 135 may include a hole transport layer. Alternatively, the first common layer 135 may further include a hole injection layer between the anode electrode 131 and the hole transport layer.

The light emitting layer 136 on the first common layer 135 may be disposed in each of the emission areas EA. The light emitting layer 136 of each first emission area EA1, the light emitting layer 136 of each second emission area EA2, and the light emitting layer 136 of each third emission area EA3 may include organic light emitting materials having different materials or contents.

For example, the light emitting layer 136 may include an organic light emitting material that converts electron-hole pairs into light.

The organic light emitting material may include a host material and a dopant. The dopant may include a phosphorescent material or a fluorescent material.

The light emitting layer 136 of each first emission area EA1 emitting light of the first color may include a host material of carbazole biphenyl (CBP) or 1,3-bis (carbazol-9-yl) (mCP).

In addition, a dopant of the light emitting layer 136 of each first emission area EA1 may include one or more phosphorescent materials selected from bis(1-phenylisoquinoline)acetylacetonate iridium (PIQIr(acac)), bis(1-phenylquinoline)acetylacetonate iridium (PQIr(acac)), tris (1-phenylquinoline)iridium (PQIr) and octaethylporphyrin platinum (PtOEP) or may be a fluorescent material including PBD:Eu(DBM)3(Phen) or perylene.

The light emitting layer 136 of each second emission area EA2 emitting light of the second color in a wavelength band lower than that of the first color may include a host material of CBP or mCP.

In addition, a dopant of the light emitting layer 136 of each second emission area EA2 may be a phosphorescent material including Ir(ppy)3(fac tris(2-phenylpyridine)iridium) or a fluorescent material including tris(8-hydroxyquinolino)aluminum (Alq3).

The light emitting layer 136 of each third emission area EA3 emitting light of the third color in a wavelength band lower than that of the second color may include a host material of CBP or mCP.

A dopant of the light emitting layer 136 of each third emission area EA3 may be a phosphorescent material including (4,6-F2ppy)2Irpic or L2BD111.

The above description of the organic light emitting material of the light emitting layer 136 is an example, and the material of the light emitting layer 136 according to an embodiment is not necessarily limited to the above description.

The second common layer 137 under the cathode electrode 138 may be disposed in the entire display area DA including the emission areas EA. The second common layer 137 may include an electron transport layer. Alternatively, the second common layer 137 may further include an electron injection layer between the cathode electrode 138 and the electron transport layer.

The cathode electrode 138 may be disposed in the entire display area DA including the emission areas EA and may be electrically connected to the second power line (VSL of FIG. 9). The cathode electrode 138 may be referred to as a common electrode.

The cathode electrode 138 may include a transparent conductive material (TCO) capable of transmitting light, such as ITO or IZO, or a semi-transmissive conductive material such as magnesium (Mg), silver (Ag) or an alloy of Mg and Ag. When the cathode electrode 138 includes a semi-transmissive conductive material, an increase in light output efficiency by a microcavity can be expected.

For example, the light emitting element layer 130 of the display device 10, according to an embodiment, may include an anode electrode 131 respectively disposed in the emission areas EA, a bank buffer layer 132 disposed in the non-emission area NEA, which is a spaced area between the emission areas EA and covering the edge of each of the anode electrodes 131, a cathode connection electrode 133 disposed on the bank buffer layer 132 and including metal layers BTL, MNL, and TPL stacked in an undercut structure, a pixel defining layer 134 disposed on the cathode connection electrode 133, the first common layers 135 respectively disposed on the anode electrodes 131, the light emitting layers 136 respectively disposed on the first common layers 135, the second common layers 137 disposed on the pixel defining layer 134 and the light emitting layers 136, and the cathode electrode 138 disposed on the second common layer 137.

The second common layer 137 and the cathode electrode 138 disposed entirely in the display area DA may be separated by the undercut structure of the cathode connection electrode 133.

In each of the emission areas EA, the cathode electrode 138 may contact a side surface of the cathode connection electrode 133 to be electrically connected to the cathode connection electrode 133.

The pixel defining layer 134 may include an organic insulating layer such as acryl resin, epoxy resin, phenolic resin, polyamide resin, or polyimide resin.

The light emitting element layer 130 may further include a sacrificial layer disposed between the anode electrode 131 and the bank buffer layer 132. For example, the bank buffer layer 132 may be spaced apart from the anode electrode 131 in a third direction DR3 by a sacrificial layer. Also, the bank buffer layer 132 may include an undercut structure by an edge protruding from the sacrificial layer.

The sealing layer 140 is designed to block penetration of oxygen or moisture into the light emitting element layer 130 and to mitigate an electric or physical shock in respect to the circuit layer 120 and the light emitting element layer 130.

The sealing layer 140 may include a first sealing layer 141 disposed on the circuit layer 120 and covering the light emitting element layer 130. The first sealing layer 141 may include inorganic insulating material.

Alternatively, according to an embodiment, the sealing layer 140 may further include a second sealing layer 142 disposed on the first sealing layer 141, overlapping the light emitting element layer 130 and including an organic insulating material and a third sealing layer 143 disposed on the first sealing layer 141, covering the second sealing layer 142 and including an inorganic insulating material.

The second sealing layer 142 may include an organic insulating material such as acryl resin, epoxy resin, phenolic resin, polyamide resin, or polyimide resin.

The second sealing layer 142 may be prepared by dropping an organic material in a liquid state onto the first sealing layer 141, spreading the organic material widely to cover the display area DA, and then curing the spread organic material.

Accordingly, the display panel 100 of the display device 10 according to an embodiment may further include a dam for limiting a range in which the organic material of the second sealing layer 142 spreads. The dam may be disposed in the non-display area NDA and the hole peripheral area PHA.

Since the second sealing layer 142 spreads to the dams, the third sealing layer 143 may contact the first sealing layer 141 in the non-display area NDA between edges of the substrate 110 and the dams. Therefore, a sealing structure composed of inorganic materials bonded to each other can be provided.

Each of the first sealing layer 141 and the third sealing layer 143 may have a structure in which one or more inorganic layers selected from a silicon nitride layer, a silicon oxynitride layer, a silicon oxide layer, a titanium oxide layer, and an aluminum oxide layer are stacked.

The touch sensor layer 150 may be disposed on the sealing layer 140.

According to an embodiment, the touch sensor layer 150 may be disposed on the third sealing layer 143 of the sealing layer 140.

The touch sensor layer 150 may include a first sensor electrode layer (SSEL1 in FIG. 7) disposed on the sealing layer 140 and including a bridge electrode BE, a first sensor insulating layer 151 covering the first sensor electrode layer SSEL1, a second sensor electrode layer (SSEL2 of FIG. 7) disposed on the first sensor insulating layer 151 and including a driving electrode TE and a sensing electrode RE, an overcoat layer 152 covering the second sensor electrode layer SSEL2, and a second sensor insulating layer 153 covering the overcoat layer 152.

Each of the first sensor insulating layer 151 and the second sensor insulating layer 153 may have a structure in which one or more inorganic layers selected from a silicon nitride layer, a silicon oxynitride layer, a silicon oxide layer, a titanium oxide layer, and an aluminum oxide layer are stacked.

The first sensor insulating layer 151 may contact the third sealing layer 143 of the sealing layer 140 in the touch peripheral area TPA to block penetration of oxygen or moisture, and the second sensor insulating layer 153 may be in contact with the first sensor insulating layer 151.

The overcoat layer 152 may include an organic material that can be disposed in a low-temperature process. For example, the overcoat layer 152 may include a negative photoresist material.

The first sensor electrode layer SSEL1 including the bridge electrodes BE may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The second sensor electrode layer SSEL2 including the touch driving electrodes TE and the receiving electrodes RE may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The second sensor electrode layer SSEL2 may further include the dummy electrode DE disposed inside each of the touch driving electrodes TE and the receiving electrodes RE, the first and second driving lines TL1 and TL2 connected to the touch driving electrodes TE, and the sensing lines RL connected to the receiving electrodes RE.

The touch driving electrodes TE may be electrically connected to the bridge electrodes BE through sensor connection contact holes TCNT1 penetrating the second sensor insulating layer 153.

The second sensor electrode layer SSEL2 including the touch driving electrodes TE, the receiving electrodes RE, the dummy electrodes DE, the first driving lines TL1, the second driving lines TL2, and the sensing lines RL may have a structure including a low reflection layer. In this case, the amount of external light emitted (i.e., reflection of external light) after being reflected inside the display panel 100 can be reduced.

FIG. 9 is an equivalent circuit diagram of one pixel driver among a circuit layer of FIG. 3.

The circuit layer 120 of the display device 10, according to the embodiment, includes the pixel drivers PXD respectively corresponding to the emission areas EA and data lines DL transmitting data signals Vdata to the pixel drivers PXD. The pixel drivers PXD of the circuit layer 120 are electrically connected to the light emitting elements LE of the light emitting element layer 130, respectively.

The circuit layer 120 may further include first power lines VDL transmitting first power ELVDD to the pixel drivers PXD and initialization voltage lines VIL transmitting an initialization voltage Vint to the pixel drivers PXD.

In addition, the circuit layer 120 may further include scan write lines GWL transmitting scan write signals GW to the pixel drivers PXD, scan initialization lines GIL transmitting scan initialization signals G1 to the pixel drivers PXD, emission control lines ECL transmitting emission control signals EC to the pixel drivers PXD, and gate control lines GCL transmitting gate control signals GC to the pixel drivers PXD.

Referring to FIG. 9, one of the pixel drivers PXD of the circuit layer 120 may include a driving transistor DT generating a driving current for driving a light emitting element LE electrically connected to the pixel driver PXD. In addition, the pixel driver PXD may further include two or more transistors ST1 through ST6 electrically connected to the driving transistor DT and at least one capacitor PC1.

An anode electrode 131 (see FIG. 8) of the light emitting element LE may be electrically connected to the pixel driver PXD, and a cathode electrode 138 (see FIG. 8) of the light emitting element LE may be electrically connected to a second power line VSL that transmits second driving power ELVSS at a lower voltage level than the first power ELVDD.

The light emitting element LE may be an organic light emitting diode having a light emitting layer including an organic light emitting material. Alternatively, the light emitting element LE may be an inorganic light emitting element having a light emitting layer including an inorganic semiconductor. Alternatively, the light emitting element LE may be a quantum dot light emitting element having a quantum dot light emitting layer. Alternatively, the light emitting element LE may be a micro-light emitting diode.

A capacitor Cel connected in parallel to the light emitting element LE is a parasitic capacitance between the anode electrode 131 and the cathode electrode 138.

The driving transistor DT is connected in series to the light emitting element LE between a first power line VDL and the second power line VSL. For example, a first electrode (e.g., a source electrode) of the driving transistor DT may be electrically connected to the first power line VDL through a fifth transistor ST5. In addition, a second electrode (e.g., a drain electrode) of the driving transistor DT may be electrically connected to the anode electrode 131 of the light emitting element LE through a sixth transistor ST6.

The first electrode of the driving transistor DT may be electrically connected to a data line DL through a second transistor ST2.

A gate electrode of the driving transistor DT may be electrically connected to the first power line VDL through a first capacitor PC1. For example, the first capacitor PC1 may be electrically connected between the gate electrode of the driving transistor DT and the first power line VDL.

Accordingly, the electric potential of the gate electrode of the driving transistor DT may be maintained at the first power ELVDD of the first power line VDL.

Therefore, when a data signal Vdata of the data line DL is transmitted to the first electrode of the driving transistor DT through the turned-on second transistor ST2, a voltage difference corresponding to the first power ELVDD and the data signal Vdata may be generated between the gate electrode of the driving transistor DT and the first electrode of the driving transistor DT. Here, when the voltage difference between the gate electrode of the driving transistor DT and the first electrode of the driving transistor DT, for example, a gate-source voltage difference is equal to or greater than a threshold voltage, the driving transistor DT may be turned on.

Then, when the fifth transistor ST5 and the sixth transistor ST6 are turned on, the driving transistor DT may be connected in series to the light emitting element LEL between the first power line VDL and the second power line VSL. Accordingly, a drain-source current corresponding to the data signal Vdata may be generated by the turned-on driving transistor DT and supplied as the driving current of the light emitting element LEL.

Therefore, the light emitting element LEL may emit light having a luminance corresponding to the data signal Vdata.

The second transistor ST2 may be connected between the first electrode of the driving transistor DT and the data line DL.

A first transistor ST1 may be connected between the gate electrode of the driving transistor DT and the second electrode of the driving transistor DT.

The first transistor ST1 may include a plurality of sub-transistors connected in series. For example, the first transistor ST1 may include a first sub-transistor ST11 and a second sub-transistor ST12.

A first electrode of the first sub-transistor ST11 may be connected to the gate electrode of the driving transistor DT, a second electrode of the first sub-transistor ST11 may be connected to a first electrode of the second sub-transistor ST12, and a second electrode of the second sub-transistor ST12 may be connected to the second electrode of the driving transistor DT.

In this case, it is possible to prevent the electric potential of the gate electrode of the driving transistor DT from being changed by a leakage current caused by the first transistor ST1 that is not turned on.

A gate electrode of each of the second transistor ST2, the first sub-transistor ST11, and the second sub-transistor ST12 may be connected to a scan write line GWL.

Accordingly, when a scan write signal GW is received through the scan write line GWL, the second transistor ST2, the first sub-transistor ST11, and the second sub-transistor ST12 may be turned on.

At this time, the data signal Vdata may be transmitted to the first electrode of the driving transistor DT through the turned-on second transistor ST2.

In addition, the gate electrode of the driving transistor DT may have the same electric potential as the second electrode of the driving transistor DT through the turned-on first sub-transistor ST11 and second sub-transistor ST12.

Accordingly, the driving transistor DT may be turned on.

A third transistor ST3 may be connected between the gate electrode of the driving transistor DT and an initialization voltage line VIL.

The third transistor ST3 may include a plurality of sub-transistors connected in series. For example, the third transistor ST3 may include a third sub-transistor ST31 and a fourth sub-transistor ST32.

A first electrode of the third sub-transistor ST31 may be connected to the gate electrode of the driving transistor DT, a second electrode of the third sub-transistor ST31 may be connected to a first electrode of the fourth sub-transistor ST32, and a second electrode of the fourth sub-transistor ST32 may be connected to the initialization voltage line VIL.

In this case, it is possible to prevent the electric potential of the gate electrode of the driving transistor DT from being changed by a leakage current caused by the third transistor ST3 that is not turned on.

A gate electrode of each of the third sub-transistor ST31 and the fourth sub-transistor ST32 may be connected to a scan initialization line GIL.

Accordingly, when a scan initialization signal G1 is received through the scan initialization line GIL, the third sub-transistor ST31 and the fourth sub-transistor ST32 may be turned on, thereby initializing the electric potential of the gate electrode of the driving transistor DT to the initialization voltage Vint of the initialization voltage line VIL.

A fourth transistor ST4 may be connected between the anode electrode of the light emitting element LE and the initialization voltage line VIL.

A gate electrode of the fourth transistor ST4 may be connected to a gate control line GCL.

Accordingly, when a gate control signal GC is received through the gate control line GCL, the fourth transistor ST4 may be turned on.

At this time, the electric potential of the anode of the light emitting element LE may be initialized to the initialization voltage Vint of the initialization voltage line VIL through the turned-on fourth transistor ST4.

Therefore, the light emitting element LE may be prevented from being driven by a current remaining in the anode electrode.

The fifth transistor ST5 may be connected between the first electrode of the driving transistor DT and the first power line VDL.

The sixth transistor ST6 may be connected between the second electrode of the driving transistor DT and the anode electrode of the light emitting element LE.

A gate electrode of each of the fifth transistor ST5 and the sixth transistor ST6 may be connected to an emission control line ECL.

Accordingly, when an emission control signal EC is received through the emission control line ECL, the fifth transistor ST5 and the sixth transistor ST6 may be turned on, thereby supplying the drain-source current of the driving transistor DT as the driving current of the light emitting element LE.

Although the driving transistor DT and the first through sixth transistors ST1 through ST6 included in the pixel driver PXD of FIG. 9 are all N-type metal oxide semiconductor field effect transistors (MOSFETs), it should be noted that the pixel driver PXD, according to the embodiment, is not necessarily limited to the illustration in FIG. 9. For example, at least one of the driving transistor DT and the first through sixth transistors ST1 through ST6 included in the pixel driver PXD, according to the embodiment, may also be a P-type MOSFET.

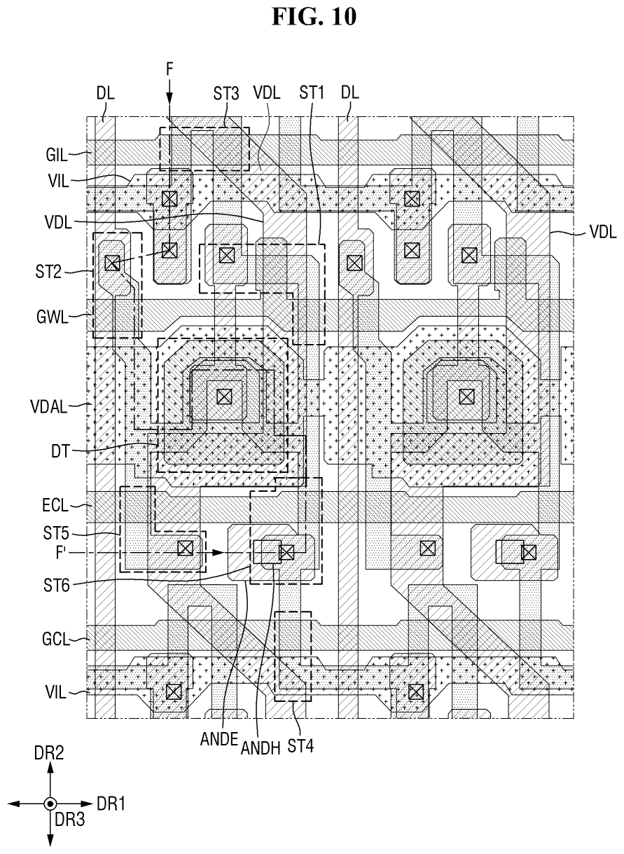

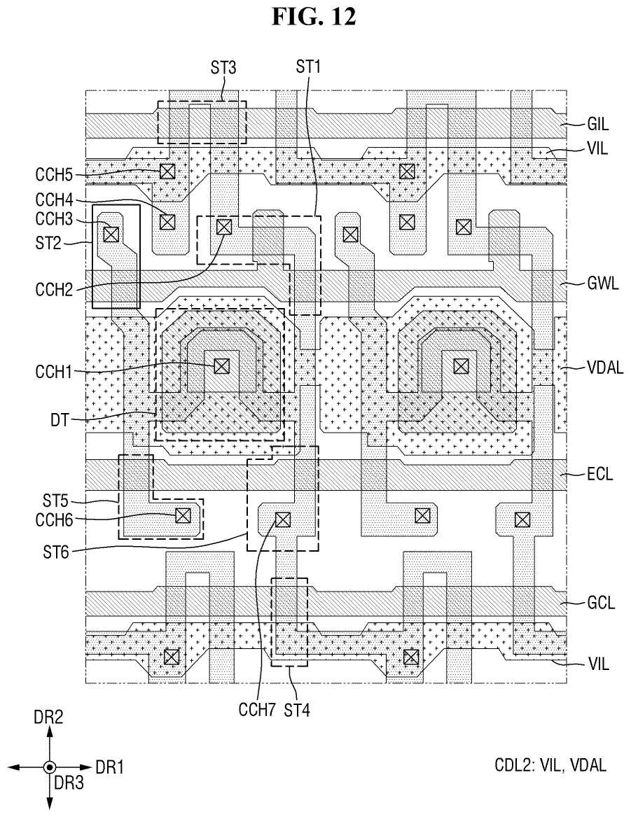

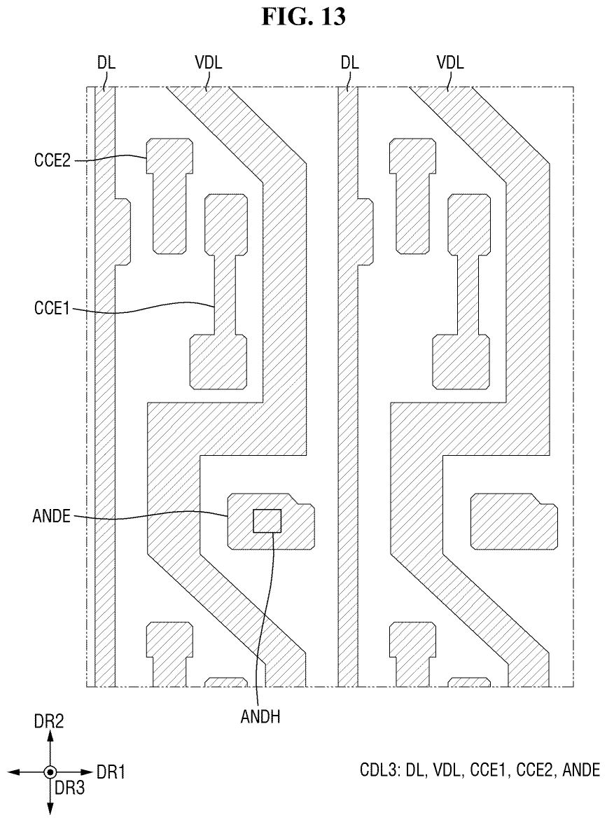

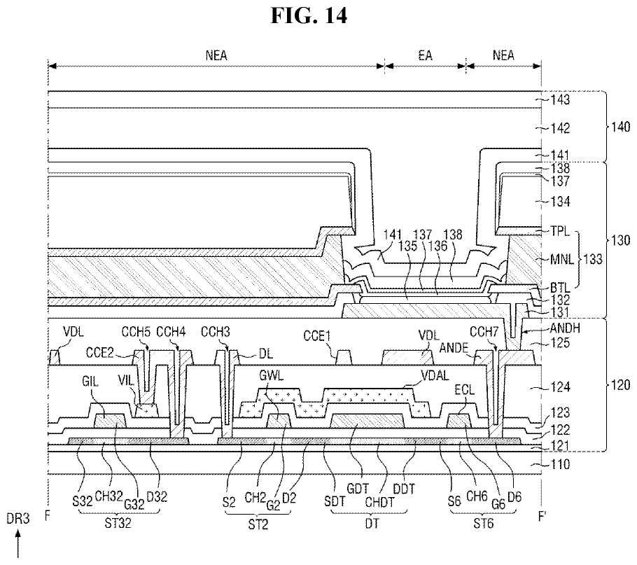

FIG. 10 is a plan view of two adjacent pixel drivers among the circuit layer of FIG. 3. FIG. 11 is a plan view of a semiconductor layer and a first conductive layer among a plan view of FIG. 10. FIG. 12 is a plan view of a semiconductor layer, a first conductive layer, and a second conductive layer among a plan view of FIG. 10. FIG. 13 is a plan view of a third conductive layer among a plan view of FIG. 10. FIG. 14 is a cross-sectional view taken along line F-F′ of FIG. 10 according to an embodiment.

Referring to FIG. 10, a pixel driver PXD of the display device 10, according to the embodiment, may include a driving transistor DT and first through sixth transistors ST1 through ST6.

The circuit layer 120 may include gates lines (GL of FIG. 15) extending in the first direction DR1. The gates lines may include a scan write line GWL, a scan initialization line GIL, an emission control line ECL, and a gate control line GCL.

The circuit layer 120 may further include initialization lines VIL and a first power auxiliary line VDAL extending in the first direction DR1.

The circuit layer 120 may further include data lines DL and a first power line VDL extending in the second direction DR2.

Referring to FIG. 11, a semiconductor layer SEL may include a channel CHDT, a first electrode SDT and a second electrode DDT of the driving transistor DT and a channel CH11, CH12, CH2, CH31, CH32, CH4, CH5 or CH6, a first electrode S11, S12, S2, S31, S32, S4, S5 or S6 and a second electrode D11. D12, D2, D31, D32, D4, D5 or D6 of each of the first through sixth transistors ST1 through ST6.

The first conductive layer CDL1 may include a gate electrode GDT of the driving transistor DT, the scan write line GWL, the scan initialization line GIL, the emission control line ECL, and the gate control line GCL.

The semiconductor layer SEL may include any one semiconductor material of polysilicon, amorphous silicon, and an oxide semiconductor.

The semiconductor layer SEL excluding portions overlapping the first conductive layer CDL1 (GDT. GWL, GIL, ECL and GCL) may maintain semiconductor characteristics, and include respective channels CH11, CH12, CH2, CH31, CH32, CH4, CH5, CH6 of transistors DT and ST1 to ST6. The remaining part of the semiconductor layer SEL may be conductive, and may include the first electrodes S11. S12, S2, S31, S32, S4, S5, S6 and the second electrodes D11, D12, D2, D31, D32, D4, D5, D6 of each of the transistors DT and ST1 to ST6.

The first conductive layer CDL1 may be a single layer or a multilayer including any one or more selected from molybdenum (Mo), aluminum (Al), chromium (Cr), gold (Au), titanium (Ti), nickel (Ni), neodymium (Nd), copper (Cu), and alloys thereof.

A gate electrode G11 of a first sub-transistor ST11, a gate electrode G12 of a second sub-transistor ST12, and a gate electrode G2 of the second transistor ST2 may be different portions of the scan write line GWL.

A gate electrode G31 of a third sub-transistor ST31 and a gate electrode G32 of a fourth sub-transistor ST32 may be different portions of the scan initialization line GIL.

A gate electrode G4 of the fourth transistor ST4 may be a portion of the gate control line GCL.

A gate electrode G5 of the fifth transistor ST5 and a gate electrode G6 of the sixth transistor ST6 may be different portions of the emission control line ECL.

The channel CHDT of the driving transistor DT overlaps the gate electrode GDT of the driving transistor DT, and both ends of the channel CHDT of the driving transistor DT are connected to the first electrode SDT of the driving transistor DT and the second electrode DDT of the driving transistor DT, respectively.

The first electrode SDT of the driving transistor DT may be connected to the second electrode D2 of the second transistor ST2 and the second electrode D5 of the fifth transistor ST5.

The second electrode DDT of the driving transistor DT may be connected to the first electrode S11 of the first sub-transistor ST11 and the second electrode D6 of the sixth transistor ST6.

The first transistor ST1 may include the first sub-transistor ST11 and the second sub-transistor ST12 connected in series.

The channel CH11 of the first sub-transistor ST11 overlaps the gate electrode G11 of the first sub-transistor ST11 which is a portion of the scan write line GWL, and both ends of the channel CH11 of the first sub-transistor ST11 are connected to the first electrode S11 of the first sub-transistor ST11 and the second electrode D11 of the first sub-transistor ST11, respectively.

The second electrode D11 of the first sub-transistor ST11 may be connected to the first electrode S12 of the second sub-transistor ST12.

The channel CH12 of the second sub-transistor ST12 overlaps the gate electrode G12 of the second sub-transistor ST12, which is a portion of the scan write line GWL, and both ends of the channel CH12 of the second sub-transistor ST12 are connected to the first electrode S12 of the second sub-transistor ST12 and the second electrode D12 of the second sub-transistor ST12, respectively.

The second electrode D12 of the second sub-transistor ST12 may be connected to the first electrode S31 of the third sub-transistor ST31.

The channel CH2 of the second transistor ST2 overlaps the gate electrode G2 of the second transistor ST2 which is a portion of the scan write line GWL, and both ends of the channel CH2 of the second transistor ST2 are connected to the first electrode S2 of the second transistor ST2 and the second electrode D2 of the second transistor ST2.

The third transistor ST3 may include the third sub-transistor ST31 and the fourth sub-transistor ST32 connected in series.

The channel CH31 of the third sub-transistor ST31 overlaps the gate electrode G31 of the third sub-transistor ST31 which is a portion of the scan initialization line GIL, and both ends of the channel CH31 of the third sub-transistor ST31 are connected to the source electrode S31 of the third sub-transistor ST31 and the drain electrode D31 of the third sub-transistor ST31, respectively.

The drain electrode D31 of the third sub-transistor ST31 may be connected to the source electrode S32 of the fourth sub-transistor ST32.

The channel CH32 of the fourth sub-transistor ST32 overlaps the gate electrode G32 of the fourth sub-transistor ST32 which is a part of the scan initialization line GIL, and both ends of the channel CH32 of the fourth sub-transistor ST32 are connected to the source electrode S32 of the fourth sub-transistor ST32 and the drain electrode D32 of the fourth sub-transistor ST32, respectively.

The channel CH4 of the fourth transistor ST4 overlaps the gate electrode G4 of the fourth transistor ST4 which is a portion of a bias control line BCL, and both ends of the channel CH4 of the fourth transistor ST4 are connected to the first electrode S4 of the fourth transistor ST4 and the second electrode D4 of the fourth transistor ST4, respectively.

The second electrode D4 of the fourth transistor ST4 may be connected to the second electrode D6 of the sixth transistor ST6.

The channel CH5 of the fifth transistor ST5 overlaps the gate electrode G5 of the fifth transistor ST5 which is a portion of the emission control line ECL, and both ends of the channel CH5 of the fifth transistor ST5 are connected to the first electrode S5 of the fifth transistor ST5 and the second electrode D5 of the fifth transistor ST5, respectively.

The channel CH6 of the sixth transistor ST6 overlaps the gate electrode G6 of the sixth transistor ST6 which is a portion of the emission control line ECL, and both ends of the channel CH6 of the sixth transistor ST6 are connected to the first electrode S6 of the sixth transistor ST6 and the second electrode D6 of the sixth transistor ST6, respectively.

Referring to FIG. 12, the second conductive layer CDL2 may include the initialization voltage line VIL and the first power auxiliary line VDAL. The initialization voltage line VIL and the first power auxiliary line VDAL may extend in the first direction DR1.

The second conductive layer CDL2 may be a multilayer including two or more of molybdenum (Mo), aluminum (Al), chromium (Cr), gold (Au), titanium (Ti), nickel (Ni), neodymium (Nd), and copper (Cu).

A portion of the first power auxiliary line VDAL may overlap the gate electrode GDT of the driving transistor DT. Accordingly, a first capacitor PC1 may be provided by an overlap area between a first power sub-line VDSBL and the gate electrode GDT of the driving transistor DT.

The circuit layer 120 may include first through seventh connection contact holes CCH1 through CCH7 penetrating at least one of a gate insulating layer (122 of FIG. 14) covering the semiconductor layer SEL, an interlayer insulating layer (123 of FIG. 14) covering the first conductive layer CDL1, and a first planarization layer (124 of FIG. 14) covering the second conductive layer CDL2.

The first connection contact hole CCH1 overlaps the gate electrode GDT of the driving transistor DT.

The second connection contact hole CCH2 overlaps a contact point (D12 and S31 of FIG. 11) between the first transistor ST1 and the third transistor ST3.

The third connection contact hole CCH3 overlaps the first electrode S2 of the second transistor ST2.

The fourth connection contact hole CCH4 overlaps the second electrode (D32 of FIG. 11) of the fourth sub-transistor (ST32 of FIG. 11) of the third transistor ST3.

The fifth connection contact hole CCH5 overlaps the initialization voltage line VIL.

The sixth connection contact hole CCH6 overlaps the first electrode (S5 of FIG. 11) of the fifth transistor ST5.

The seventh connection contact hole CCH7 overlaps a contact point (D4 and D6 of FIG. 11) between the fourth transistor ST4 and the sixth transistor ST6.

As illustrated in FIG. 14, the third connection contact hole CCH3, the fourth connection contact hole CCH4 and the seventh connection contact hole CCH7 overlapping the semiconductor layer SEL, among the first through seventh connection contact holes CCH1 through CCH7, may penetrate the planarization layer 124, the interlayer insulating layer 123, and the gate insulating layer 122 to expose the semiconductor layer SEL. Likewise, the second connection contact hole CCH2 and the sixth connection contact hole CCH6 overlapping the semiconductor layer SEL, among the first through seventh connection contact holes CCH1 through CCH7, may penetrate the planarization layer 124, the interlayer insulating layer 123, and the gate insulating layer 122 to expose the semiconductor layer SEL.

The first connection contact hole CCH1 may penetrate the planarization layer 124 and the interlayer insulating layer 123 to expose the gate electrode GDT of the driving transistor DT including the first conductive layer CDL1.

The fifth connection contact hole CCH5 may penetrate the planarization layer 124 to expose the initialization voltage line VIL including the second conductive layer CDL2.

Referring to FIG. 13, the third conductive layer CDL3 may include the data lines DL, the first power lines VDL, a first connection electrode CCE1, a second connection electrode CCE2, and an anode connection electrode ANDE.

The data lines DL and the first power lines VDL may extend in the second direction DR2.

The third conductive layer CDL3 may be a multilayer including two or more of molybdenum (Mo), aluminum (Al), chromium (Cr), gold (Au), titanium (Ti), nickel (Ni), neodymium (Nd), and copper (Cu).

Referring to FIGS. 10, 12 and 13, the first connection electrode CCE1 may be electrically connected to the gate electrode GDT of the driving transistor DT through the first connection contact hole CCH1 and may be electrically connected to the first transistor ST1 and the third transistor ST3 through the second connection contact hole CCH2.

Accordingly, the gate electrode GDT of the driving transistor DT may be electrically connected to the first transistor ST1 and the third transistor ST3 through the first connection electrode CCE1, the first connection contact hole CCH1, and the second connection contact hole CCH2.

A data line DL may be electrically connected to the first electrode S2 of the second transistor ST2 through the third connection contact hole CCH3.

The second connection electrode CCE2 may be electrically connected to the second electrode (D32 of FIG. 11) of the fourth sub-transistor (ST32 of FIG. 8) through the fourth connection contact hole CCH4 and may be electrically connected to the initialization voltage line VIL through the fifth connection contact hole CCH5.

Accordingly, the second electrode (D32 of FIG. 11) of the fourth sub-transistor (ST32 of FIG. 11) may be electrically connected to the initialization voltage line VIL through the second connection electrode CCE2, the fourth connection contact hole CCH4, and the fifth connection contact hole CCH5.

A first power line VDL may be electrically connected to the first electrode (S5 of FIG. 11) of the fifth transistor ST5 through the sixth connection contact hole CCH6.

The anode connection electrode ANDE may be electrically connected to the fourth transistor ST4 and the sixth transistor ST6 through the seventh connection contact hole CCH7. Referring to FIG. 14, the circuit layer 120 may include the semiconductor layer SEL

(CHDT. SDT. DDT, CH2, S2, D2, CH32, S32, D32, CH6, S6 and D6) on the substrate 110, the first conductive layer CDL1 (GWL, GIL, ECL and GDT) which is disposed on the gate insulating layer 122 covering the semiconductor layer SEL (CHDT, SDT, DDT, CH2, S2, D2, CH32, S32, D32, CH6, S6 and D6), the second conductive layer CDL2 (VIL and VDAL) which is disposed on the interlayer insulating layer 123 covering the first conductive layer CDL1 (GWL, GIL, ECL and GDT), the third conductive layer CDL3 (DL, VDL, CCE1, CCE2 and ANDE) which is disposed on the planarization layer 124 covering the second conductive layer CDL2 (VIL and VDAL) and includes second direction lines VDRL extending in the second direction DR2, and a second planarization layer 125 which covers the third conductive layer CDL3 (DL, VDL, CCE1, CCE2 and ANDE).

The circuit layer 120 may further include a buffer layer 121 disposed between the substrate 110 and the semiconductor layer SEL (CHDT, SDT, DDT, CH2, S2, D2, CH32, S32, D32, CH6, S6 and D6).

Each of the buffer layer 121, the gate insulating layer 122, and the interlayer insulating layer 123 may include at least one inorganic layer. For example, each of the buffer layer 121, the gate insulating layer 122, and the interlayer insulating layer 123 may be a multilayer in which one or more inorganic layers selected from silicon nitride, silicon oxynitride, silicon oxide, titanium oxide, and aluminum oxide are alternately stacked.

Each of the planarization layer 124 and the via layer 125 may include an organic layer such as acryl resin, epoxy resin, phenolic resin, polyamide resin, or polyimide resin.

The light emitting element layer 130 may be disposed on the via layer 125 of the circuit layer 120.

The light emitting element layer 130 and the sealing layer 140 may be at least similar to corresponding elements that have been described with reference to FIG. 8.

FIG. 15 is a layout view illustrating an example of data lines and first power lines of a circuit layer disposed in portion C of FIG. 4.

Referring to FIG. 15, the display panel 100 of the display device 10, according to an embodiment, further includes a through hole THH disposed in a hole area HLA surrounded by the display area DA, and sealing auxiliary units ASEN disposed in the hole peripheral area PHA between the display area DA and the hole area HLA and sequentially surrounding the edge of the hole area HLA.

In addition, according to an embodiment, the data lines DL of the circuit layer 120 include hole intersection data lines HINDL crossing the hole area HLA and the hole peripheral area PHA. Each of the hole intersection data lines HINDL includes a hole bypass unit HDEP disposed in the hole peripheral area PHA.

The hole bypass units HDEP of the hole intersection data lines HINDL overlap the sealing auxiliary units ASEN. For example, as the hole bypass units HDEP and the sealing auxiliary units ASEN included in the hole peripheral area PHA are disposed adjacent to each other in the first direction DR1 or the second direction DR2, the width of the hole peripheral area PHA may be reduced.

The data lines DL of the circuit layer 120 might not only include the hole intersection data lines HINDL, but also include general data lines DL′ extending in the second direction DR2 from between both ends of the display area DA in the second direction DR2.

Each of the hole intersection data lines HINDL may include a first hole-adjacent portion HADP1 adjacent to one side of the hole area HLA in the second direction DR2, a second hole-adjacent portion HADP2 adjacent to the other side of the hole area HLA in the second direction DR2, and a hole bypass unit HDEP connecting the first hole-adjacent portion HADP1 and the second hole-adjacent portion HADP2.

The first hole-adjacent portion HADP1 may extend in the second direction DR2 between one side of the edge of the display area DA adjacent to the sub-area SBA in the second direction DR2 and one side of the hole area HLA in the second direction DR2.

The second hole-adjacent portion HADP2 may extend in the second direction DR2 between the other side of the display area DA in the second direction DR2 and the other side of the hole area HLA in the second direction DR2.

The hole bypass unit HDEP may be disposed in the hole peripheral area PHA and bypass the hole area HLA along the edge of the hole area HLA to connect the first hole-adjacent portion HADP1 and the second hole-adjacent portion HADP2.

The first power line VDL extending in the second direction DR2 of the circuit layer 120 may include hole intersection power lines HINVD crossing the hole area HLA and the hole peripheral area PHA, and general power lines VDL′ extending in the second direction DR2 between both ends of the display area DA in the second direction DR2.

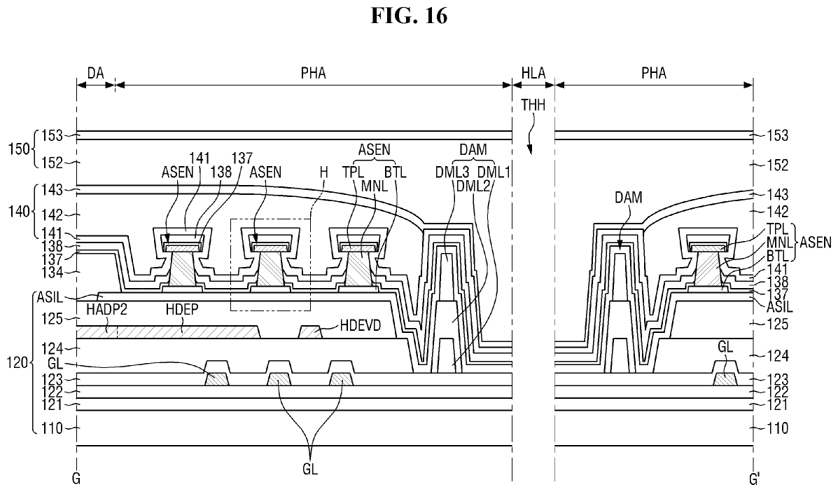

Here, each of the hole intersection power lines HINVD may include a portion (HDEVD of FIG. 16) disposed in the hole peripheral area PHA and bypassing the hole area HLA along an edge of the hole area HLA.

In addition, each of the gate lines GL crossing the hole area HLA and the hole peripheral area PHA among the gate lines GL may include a portion disposed in the hole peripheral area PHA and bypassing the hole area HLA along an edge of the hole area HLA.

FIG. 16 is a cross-sectional view taken along line G-G′ of FIG. 15 according to an embodiment.

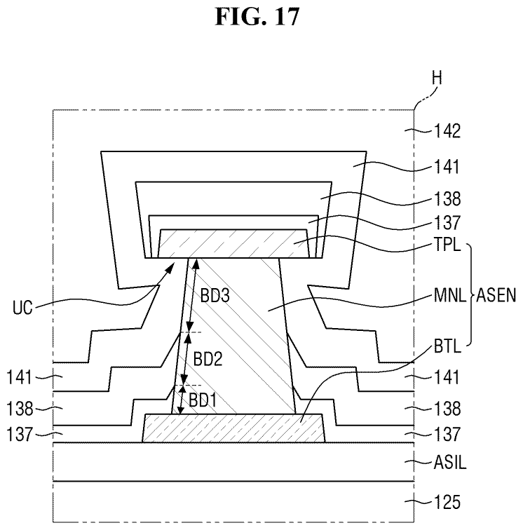

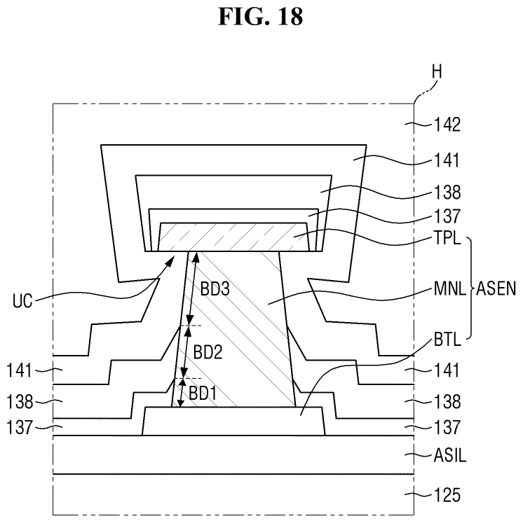

Referring to FIG. 16, each of the sealing auxiliary units ASEN of the hole peripheral area PHA may include metal layers (BTL, MNL, and TPL of FIGS. 17 and 18) stacked in an undercut structures (UC of FIGS. 17 and 18).

As described above, the circuit layer 120 may include the via layer 125 covering the data lines DL on the planarization layer 124.

For example, the first hole-adjacent portion HADP1, the second hole-adjacent portion HADP2, and the hole bypass unit HDEP of the hole intersection data line HINDL are all disposed on the planarization layer 124 and covered with the via layer 125.

Similarly, the hole intersection power lines HINVD and its hole bypass portion HDEVD are disposed on the planarization layer 124 and covered with a via layer 125.

For example, according to an embodiment, in order for the hole bypass unit HDEP of the hole intersection data line HINDL to be disposed in the hole peripheral area PHA, the planarization layer 124 and the via layer 125 may extend to the hole peripheral area PHA.

The sealing auxiliary units ASEN of the hole peripheral area PHA may be disposed on the via layer 125 covering the hole bypass units HDEP of the hole intersection data lines HINDL.

According to an embodiment, the display panel of the display device 10 may further include an auxiliary insulating layer ASIL disposed in at least the hole peripheral area PHA and covering the via layer 125. The auxiliary insulating layer ASIL may be a multilayer in which one or more inorganic layers selected from silicon nitride, silicon oxynitride, silicon oxide, titanium oxide, and aluminum oxide are alternately stacked.

The sealing auxiliary units ASEN may be disposed on the auxiliary insulating layer ASIL covering the via layer 125.

In this way, since the sealing auxiliary units ASEN are disposed on the auxiliary insulating layer ASIL of the inorganic insulating material rather than on the via layer 125 of the organic material, the sealing auxiliary units ASEN can be prevented from being easily detached.

Also, the second common layer 137 and the cathode electrode 138 corresponding to the display area DA may be disposed on the auxiliary insulating layer ASIL and the sealing auxiliary units ASEN in the hole peripheral area PHA. At this time, the second common layer 137 and the cathode electrode 138 may be separated by an undercut structure of each of the sealing auxiliary units ASEN.

Therefore, since the penetration path of oxygen or moisture through the second common layer 137 and the cathode electrode 138 disposed in the area around the hole peripheral area PHA is cut off by the undercut structures of the sealing auxiliary units ASEN, oxygen or moisture penetration may be delayed.

In addition, the auxiliary insulating layer ASIL covering the planarization layer 124 and the via layer 125 at least in the hole peripheral area PHA may extend to the edge of the hole area HLA, so that the interlayer insulating layer 123 of the circuit layer 120 and the first sealing layer 141 of the sealing layer 140 may be in contact with each other at the boundary between the hole peripheral area PHA and the hole area HLA.

In this way, even though the end surfaces of the planarization layer 124 and the via layer 125 in the hole peripheral area PHA are covered with the auxiliary insulating layer ASIL, a scaling structure made by bonding of inorganic materials may be prepared at the boundary between the hole peripheral area PHA and the hole area HLA. Accordingly, the hole area HLA and the hole peripheral area PHA can be prevented from being easily penetrated by oxygen or moisture.

According to an embodiment, the display panel 100 of the display device 10 may further include one or more dams DAM disposed in the hole peripheral area PHA and formed in a shape surrounding the periphery of the hole area HLA in order to prevent the second sealing layer 142 from spreading into the hole area HLA.

Each of the one or more dams DAM may include at least two among a first dam layer DML1 including the same layer as the planarization layer 124, a second dam layer DML2 including the same layer as the via layer 125, and a third dam layer DML3 including the same layer as the pixel defining layer 134.

The first sealing layer 141 and the third sealing layer 143 may extend to the hole peripheral area PHA.

Therefore, since the buffer layer 121, the gate insulating layer 122, the interlayer insulating layer 123, and the auxiliary insulating layer ASIL of the circuit layer 120 and the first sealing layer 141 and the third sealing layer 143 are stacked at the edge of the hole peripheral area PHA adjacent to the hole area HLA, the hole area HLA and the hole peripheral area PHA can be prevented from being easily penetrated by oxygen or moisture.

The overcoat layer 152 and the second sensor insulating layer 153 of the touch sensor layer 150 may be disposed not only in the display area DA, but also further disposed in the hole peripheral area PHA and the hole area HLA, and may be penetrated by the through hole THH of the hole area HLA.

FIG. 17 is an enlarged view illustrating an example of portion H of FIG. 15.

As illustrated in FIG. 17, similar to a cathode connection electrode (133 of FIG. 8), each of the sealing auxiliary units ASEN may include a main layer MNL, a bottom layer BTL disposed under the main layer MNL, and a top layer TPL disposed on the main layer MNL and having an edge protruding from the main layer MNL.

The main layer MNL may be formed of a metal material having relatively low resistance. For example, the main layer MNL may include copper (Cu) or aluminum (Al).

Side surfaces of the main layer MNL included in each of the cathode connection electrode 133 and the sealing auxiliary units ASEN may include a common bonding portion BD1 in contact with the second common layer 137, a cathode bonding portion BD2 in contact with the cathode electrode 138, and a scaling bonding portion BD3 in contact with the first sealing layer 141. To this end, the thickness of the main layer MNL may be about 6000 Å.

As described above, since the sealing bonding portion BD3 of the cathode connection electrode 133 is disposed at the edge of each of the emission areas EA as the side surface of the main layer MNL includes the sealing bonding portion BD3, the emission areas EA may be individually sealed.

In addition, since the side surface of the main layer MNL of each of the sealing auxiliary units ASEN include the scaling bonding portion BD3 in contact with the first sealing layer 141, the sealing structure of the hole peripheral area PHA may be strengthened by the sealing auxiliary units ASEN disposed in an overlapping manner to surround the edge of the hole area HLA.

Accordingly, the hole area HLA and the hole peripheral area PHA can be prevented from being easily penetrated by oxygen or moisture.

As the top layer TPL includes an edge protruding more than the main layer MNL, an undercut structure UC may be provided.

The top layer TPL may be formed of a different metal material having a difference in corrosion potential from that of the metal material of the main layer MNL. For example, the top layer TPL may include titanium (Ti) or molybdenum (Mo).

The top layer TPL may have a thickness of about 1000 Å so that each of the cathode connection electrodes 133 and each of the sealing auxiliary units ASEN may maintain an undercut structure.

The bottom layer BTL may be formed of a material capable of blocking diffusion of the metal material of the main layer MNL to the surroundings.

According to one embodiment, the bottom layer BTL may include titanium (Ti) or molybdenum (Mo).

FIG. 18 is an enlarged view illustrating another example of portion H of FIG. 15.

Referring to FIG. 18, the sealing auxiliary unit ASEN may be at least similar to corresponding elements described with reference to FIG. 17 except that the bottom layer BTL includes an inorganic insulating material.

According to an embodiment, the bottom layer BTL may be formed of an inorganic insulating material different from that of the auxiliary insulating layer ASIL,

For example, when the auxiliary insulating layer ASIL includes silicon nitride, the bottom layer BTL may include silicon oxide.

Alternatively, the auxiliary insulating layer ASIL may include silicon oxide and the bottom layer BTL may include silicon nitride.

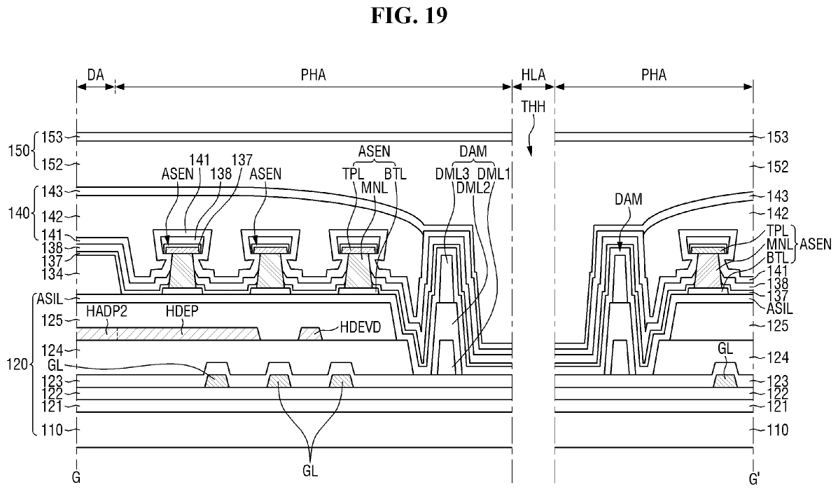

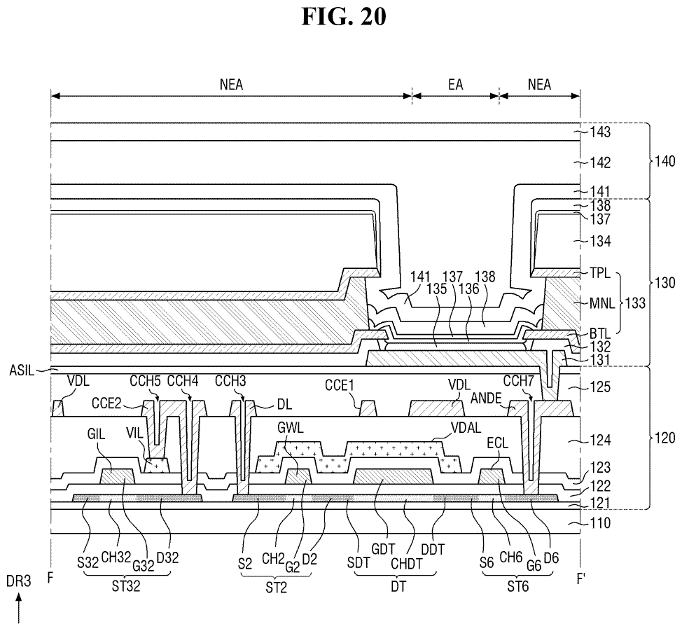

FIG. 19 is a cross-sectional view taken along line G-G′ of FIG. 15 according to an embodiment. FIG. 20 is a cross-sectional view taken along line F-F′ of FIG. 10 according to an embodiment.

Referring to FIGS. 19 and 20, the display device 10 may be at least similar to corresponding elements described with reference to FIGS. 14 and 16 except that the auxiliary insulating layer ASIL is disposed not only in the hole peripheral area PHA but in the entire main area MA to entirely cover the via layer 125.

According to an embodiment, as the via layer 125 is covered with the auxiliary insulating layer ASIL, the outgas generated in the planarization layer 124 and the via layer 125 may be prevented from flowing to the light emitting element layer 130.

In addition, since the anode electrode 131 and the bank buffer layer 132 of inorganic materials of the light emitting element layer 130 are disposed on the auxiliary insulating layer ASIL of the inorganic material, a breaking defect of the anode electrode 131 and the bank buffer layer 132 may be prevented.

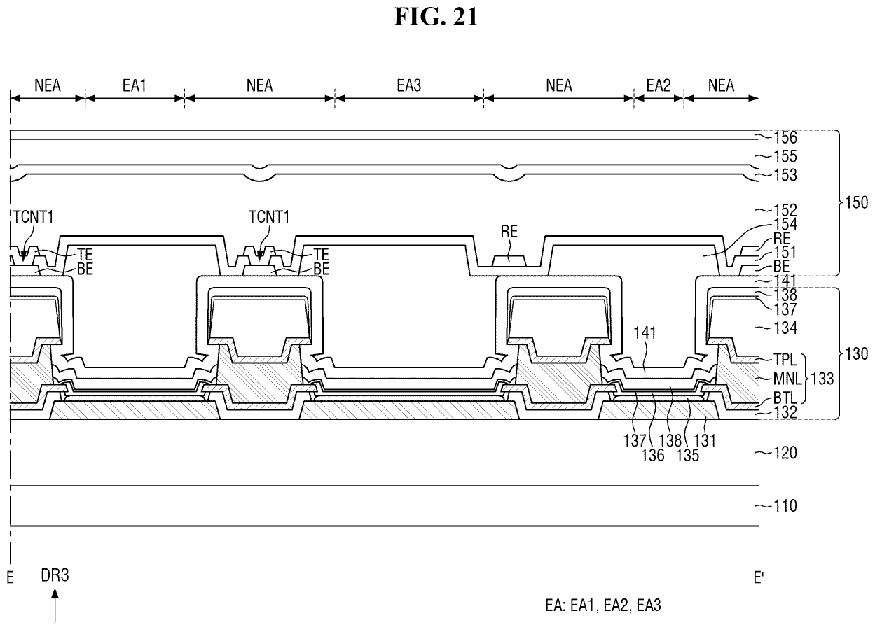

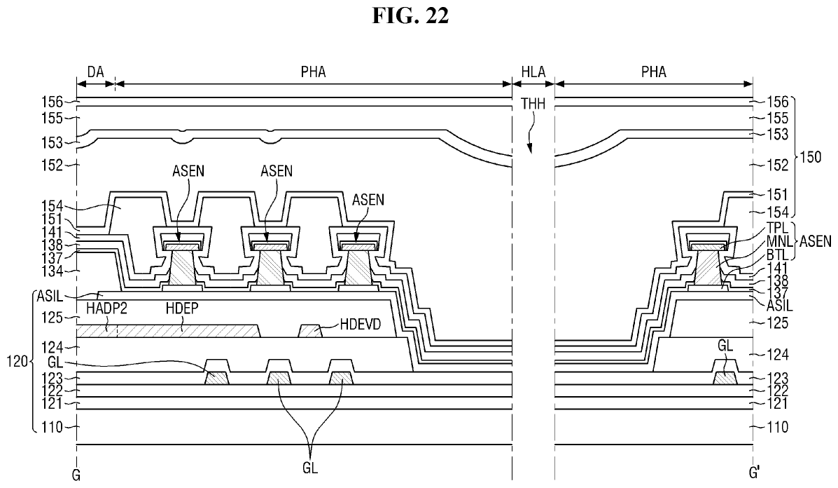

FIG. 21 is a cross-sectional view taken along line E-E′ of FIG. 7 according to an embodiment. FIG. 22 is a cross-sectional view taken along line G-G′ of FIG. 15 according to an embodiment.

Referring to FIGS. 21 and 22, the display device 10 may be at least similar to corresponding elements illustrated in FIG. 8 and FIG. 16 except that, instead of the sealing layer 140 not including the second sealing layer (142 of FIG. 16) and the third sealing layer (143 of FIG. 16), the touch sensor layer 150 further includes a first additional overcoat layer 154 and a second additional overcoat layer 155.

For example, the touch sensor layer 150 may include a first additional overcoat layer 154 disposed on the first sealing layer 141 in each emission areas EA of the display area DA disposed on the first sealing layer 141, a first sensor electrode layer SSEL1: BE disposed on the first sealing layer 141 in the non-emission area NEA of the display area DA, a first sensor insulating layer 151 disposed on the first sensor electrode layer SSEL1: BE and the first additional overcoat layer 154, a second sensor electrode layer SSEL2: TE and RE disposed on the first sensor insulating layer 151, an overcoat layer 152 covering the second sensor electrode layer SSEL2, a second sensor insulating layer 153 covering the overcoat layer 152, and a second additional overcoat layer 155 disposed evenly covering the second sensor insulating layer 153.

In addition, the touch sensor layer 150 may further include an additional cover insulating layer 156 covering the second additional overcoat layer 155.

Like the overcoat layer 152, the first additional overcoat layer 154 may be disposed through a low-temperature process and may be formed of an organic material that does not require a curing process. For example, the first additional overcoat layer 154 may include a negative photoresist material.

According to an embodiment, in the non-emission area NEA of the display area DA, the first sealing layer 141 may be exposed without being covered with the first additional overcoat layer 154. Accordingly, the first sensor electrode layer SSEL1: BE may be disposed on the first sealing layer 141 of the non-emission area NEA.

In each of the emission areas EA of the display area DA, the first additional overcoat layer 154 may be overlapped with a light emitting layer 136. For example, the cathode connection electrode 133 may be opened in each of the emission areas EA, and the opening portions of the cathode connection electrode 133 may be filled with the first additional overcoat layer 154.

In addition, in the hole peripheral area PHA, the first additional overcoat layer 154 may be disposed between the sealing auxiliary units ASEN. For example, the spaces between the scaling auxiliary units ASEN may be filled with the first additional overcoat layer 154.

Accordingly, the sealing auxiliary units ASEN and the cathode connection electrode 133 may be supported by the first additional overcoat layer 154.

Like described above, according to an embodiment, since the sealing layer 140 does not include the second sealing layer 142, not only is the third sealing layer 143 covering the second sealing layer 142 removed, but the dam DAM may be removed from the hole peripheral area PHA.

Accordingly, the width of the hole peripheral area PHA around the hole may be further reduced as much as the dam DAM is removed.

In addition, since the touch sensor layer 150 further includes a first additional overcoat layer 154 disposed on the first sealing layer 141 instead of the second sealing layer 142 removed, the circuit layer 120 and the light emitting element layer 130 may be protected from cracks caused by physical impact and foreign substances.

In addition, as the touch sensor layer 150 further includes the second additional overcoat layer 155, a decrease in touch sensing sensitivity due to a curved surface may be prevented.

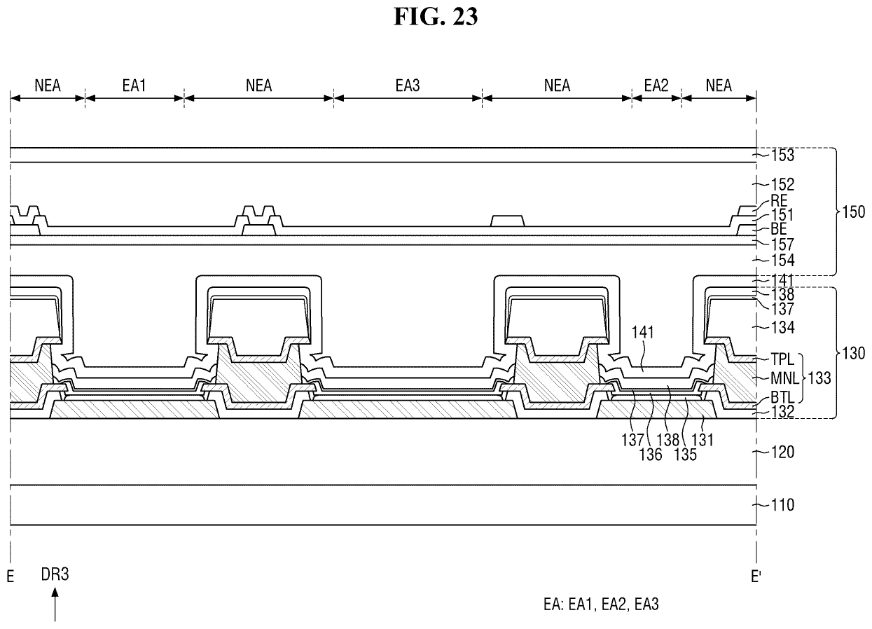

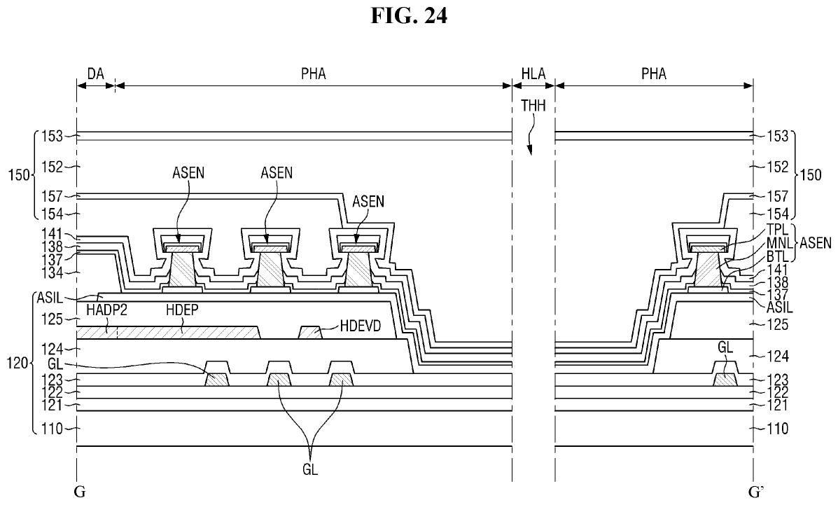

FIG. 23 is a cross-sectional view taken along line E-E′ of FIG. 7 according to an embodiment. FIG. 24 is a cross-sectional view taken along line G-G′ of FIG. 15 according to an embodiment.

Referring to FIGS. 23 and 24, the display device 10 may be at least similar to corresponding elements illustrated in FIG. 8 and FIG. 16 except that, instead of the sealing layer 140 not including the second sealing layer (142 of FIG. 16) and the third sealing layer (143 of FIG. 143), the touch sensor layer 150 includes a first additional overcoat layer 154 disposed on the first sealing layer 141 in the display area DA and a first sensor electrode layer SSEL1: BE disposed on an additional sensor insulating layer 157.

According to an embodiment, the touch sensor layer 150 may include a first additional overcoat layer 154 evenly disposed on the first sealing layer 141 in the display area DA, an additional sensor insulating layer 157 disposed on the first additional overcoat layer 154, a first sensor electrode layer SSEL1: BE disposed on the additional sensor insulating layer 157, a first sensor insulating layer 151 disposed on the first sensor electrode layer SSEL1: BE, a second sensor electrode layer SSEL2: TE and RE disposed on the first sensor insulating layer 151, an overcoat layer 152 evenly covering the second sensor electrode layer SSEL2: TE and RE, and a second sensor insulating layer 153 disposed on the overcoat layer 152.

The first additional overcoat layer 154 may be spaced apart from the hole area HLA, and at least one of the sealing auxiliary units ASEN might not be completely covered with the first additional overcoat layer 154.

For example, the first additional overcoat layer 154 may fill spaces between the sealing auxiliary units ASEN and extend to one of the sealing auxiliary units ASEN closest to the hole area HLA.

Accordingly, the additional sensor insulating layer 157 may be in contact with the first sealing layer 141 in a portion of the hole peripheral area PHA adjacent to the edge of the hole area HLA.

As described above, according to an embodiment, as the first additional overcoat layer 154 may be evenly disposed, even if the second additional overcoat layer (155 of FIG. 22) on the second sensor insulating layer 153 is not included, it may be convenient for the touch sensor layer 150 to include an even surface. Accordingly, while the touch sensor layer 150 may have a smaller thickness, deterioration in touch sensing sensitivity may be prevented.

However, the effects of the present disclosure are not necessarily restricted to the one set forth herein. The above and other effects of the present disclosure will become more apparent to one of daily skill in the art to which the present disclosure pertains by referencing the claims.

What is claimed is:

1. A display device, comprising:
a substrate including a display area in which emission areas are disposed, a non-display area proximate to the display area, a hole area at least partially surrounded by the display area, and a hole peripheral area disposed between the hole area and the display area;
a circuit layer disposed on the substrate;
a light emitting element layer disposed on the circuit layer and including light emitting elements disposed within the emission areas;
a through hole disposed on the hole area and passing through the substrate; and
sealing auxiliary units disposed in the hole peripheral area and at least partially surrounding an edge of the hole area,
wherein the circuit layer comprises:
pixel drivers electrically connected to the light emitting elements; and
data lines transmitting data signals to the pixel drivers,
wherein hole intersection data lines, among the data lines, cross the hole area and the hole peripheral area, and each of the hole intersection data lines include a hole bypass unit disposed in the hole peripheral area, and
wherein the hole bypass unit of the hole intersection data lines overlap the sealing auxiliary units.

2. The display device of claim 1,
wherein the substrate further comprises a sub-area protruding from the non-display area proximate to one side of the edge of the display area,
wherein each of the hole intersection data lines further comprises:
a first hole adjacent unit extending between the one side of the edge of the display area and one side of the hole area, and
a second hole adjacent unit extending between the other side of the edge of the display area and the other side of the hole area,
wherein the hole bypass unit bypasses the hole area along the edge of the hole area and is connected between the first hole adjacent unit and the second hole adjacent unit.

3. The display device of claim 2, wherein each of the sealing auxiliary units include metal layers stacked in an undercut structure.

4. The display device of claim 3,
wherein the circuit layer further includes a via layer covering the data lines and an auxiliary insulating layer disposed in the hole peripheral area, covering the via layer, and including an inorganic insulating material layer,
wherein the light emitting element layer is disposed on the via layer, and
wherein the sealing auxiliary units are disposed on the auxiliary insulating layer.

5. The display device of claim 4,
wherein light emitting element layer comprises:
anode electrodes respectively disposed in the emission areas;
a bank buffer layer disposed in a non-emission area which is between the emission areas and covering the edge of each of the anode electrodes;
a cathode connection electrode disposed on the bank buffer layer and including metal layers stacked in an undercut structure;
a pixel defining layer disposed on the cathode connection electrode;
first common layers respectively disposed on the anode electrodes;
light emitting layers respectively disposed on the first common layers;
a second common layer disposed on the pixel defining layer and the light emitting layers; and
a cathode electrode disposed on the second common layer,
wherein the second common layer and the cathode electrode are separated by the undercut structure of the cathode connection electrode and the undercut structure of each of the sealing auxiliary units,
wherein the cathode electrode is in contact with a side surface of the cathode connection electrode and is electrically connected to the cathode connection electrode in each emission area, and
wherein the first common layer, the light emitting layer and the second common layer are provided in a stacked structure between the anode electrode and the cathode electrode in each emission area.

6. The display device of claim 5, wherein each of the cathode connection electrode and the sealing auxiliary units comprise:
a main layer;
a bottom layer disposed under the main layer; and
a top layer disposed on the main layer and having an edge protruding to a greater extent than the main layer.

7. The display device of claim 6,
wherein the main layer includes aluminum (Al) or copper (Cu), and
wherein the top layer includes titanium (Ti) or molybdenum (Mo).

8. The display device of claim 7,
wherein the bottom layer includes titanium (Ti) or molybdenum (Mo).

9. The display device of claim 7,
wherein the bottom layer includes an inorganic insulating material that is not present in the auxiliary insulating layer.

10. The display device of claim 6,
further comprising a first sealing layer disposed on the circuit layer, covering the light emitting element layer, and including an inorganic insulating material,
wherein the first sealing layer is in contact with the auxiliary insulating layer in the hole peripheral area.

11. The display device of claim 10,
wherein the side surface of the main layer comprises:
a common bonding portion in contact with the second common layer;
a cathode bonding portion in contact with the cathode electrode; and
a sealing bonding portion in contact with the first sealing layer.

12. The display device of claim 11, further comprising:
a second sealing layer disposed on the first sealing layer, covering the light emitting element layer and the sealing auxiliary units and including an organic insulating material; and
a third sealing layer disposed on the first sealing layer, covering the second sealing layer, and including an inorganic insulating material,
wherein the third sealing layer is in contact with the first sealing layer in the hole peripheral area.

13. The display device of claim 11, wherein the auxiliary insulating layer covers the via layer.

14. The display device of claim 11, further comprising a touch sensor layer disposed on the first sealing layer,
wherein the touch sensor layer comprises:
a first additional overcoat layer disposed on the first sealing layer in each of the emission areas;
a first sensor electrode layer disposed on the first sealing layer in the non-emission area;
a first sensor insulating layer disposed on the first sensor electrode layer and the first additional overcoat layer;
a second sensor electrode layer disposed on the first sensor insulating layer;
an overcoat layer covering the second sensor electrode layer;
a second sensor insulating layer covering the overcoat layer; and
a second additional overcoat layer evenly covering the second sensor insulating layer,
wherein the first additional overcoat layer is disposed between the sealing auxiliary units in the hole peripheral area, and
wherein the first sensor insulating layer is in contact with the first sealing layer on each of the cathode connection electrode and the sealing auxiliary units.

15. The display device of claim 11, further comprising a touch sensor layer disposed on the first sealing layer,
wherein the touch sensor layer comprises:
a first additional overcoat layer disposed on the first sealing layer in the display area;
an additional sensor insulating layer disposed on the first additional overcoat layer;
a first sensor electrode layer disposed on the additional sensor insulating layer;
a first sensor insulating layer disposed on the additional sensor insulating layer and the first sensor electrode layer;
a second sensor electrode layer disposed on the first sensor insulating layer;
an overcoat layer evenly covering the second sensor electrode layer; and
a second sensor insulating layer disposed on the overcoat layer,
wherein the additional sensor insulating layer is in contact with the first sealing layer in a portion adjacent to the edge of the hole area within the hole peripheral area.

16. A display device, comprising:
a substrate including a display area in which emission areas are disposed, a non-display area at least partially surrounding the display area, a hole area at least partially surrounded by the display area, and a hole peripheral area disposed between the hole area and the display area;
a circuit layer disposed on the substrate;
a light emitting element layer disposed on the circuit layer and including light emitting elements disposed within the emission areas;
a through hole disposed on the hole area and passing through the substrate; and
sealing auxiliary units disposed in the hole peripheral area, at least partially surrounding an edge of the hole area, and including metal layers stacked in an undercut structure,
wherein the circuit layer comprises:
pixel drivers electrically connected to the light emitting elements;
data lines transmitting data signals to the pixel drivers;
a via layer covering the data lines; and
an auxiliary insulating layer disposed in the hole peripheral area, covering the via layer, and including an inorganic insulating material,
wherein the data lines include hole intersection data lines crossing the hole area and the hole peripheral area,
wherein each of the hole intersection data lines include a hole bypass unit disposed in the hole peripheral area, and
wherein the sealing auxiliary units are disposed on the auxiliary insulating layer and overlap the hole bypass units of the hole intersection data lines.

17. The display device of claim 16, wherein the auxiliary insulating layer covers the via layer.

18. The display device of claim 16,
wherein the substrate further comprises a sub-area protruding from the non-display area proximate to one side of the edge of the display area,
wherein each of the hole intersection data lines further comprises a first hole adjacent unit extending between the one side of the edge of the display area and one side of the hole area, and a second hole adjacent unit extending between the other side of the edge of the display area and the other side of the hole area,
wherein the hole bypass unit bypasses the hole area along the edge of the hole area and is connected between the first hole adjacent unit and the second hole adjacent unit.

19. The display device of claim 18, wherein the light emitting element layer comprises:
anode electrodes disposed on the via layer in each of the emission areas;
a bank buffer layer disposed in a non-emission area which is between the emission areas and covering the edge of each of the anode electrodes;
a cathode connection electrode disposed on the bank buffer layer and including metal layers stacked in an undercut structure;
a pixel defining layer disposed on the cathode connection electrode layer;
first common layers respectively disposed on the anode electrodes;
light emitting layers respectively disposed on the first common layers;
a second common layer disposed on the pixel defining layer and the light emitting layers; and
a cathode electrode disposed on the second common layer,
wherein the second common layer and the cathode electrode are separated by the undercut structure of the cathode connection electrode and the undercut structure of each of the sealing auxiliary units,
wherein the cathode electrode is in contact with the side surface of the cathode connection electrode to be electrically connected to the cathode connection electrode in each emission area, and
wherein the first common layer, the light emitting layer and the second common layer are provided in a stacked structure between the anode electrode and the cathode electrode in each emission area.

20. The display device of claim 19, wherein each of the cathode connection electrode and the sealing auxiliary units comprise:
a main layer;
a bottom layer disposed under the main layer; and
a top layer disposed on the main layer and having an edge protruding to a greater extent than the main layer,
wherein the main layer includes aluminum (Al) or copper (Cu), and
wherein the top layer includes titanium (Ti) or molybdenum (Mo).

21. The display device of claim 20,
wherein the bottom layer includes titanium (Ti) or molybdenum (Mo).

22. The display device of claim 20,
wherein the bottom layer includes inorganic insulating material that is not present in the auxiliary insulating layer.

23. The display device of claim 19,
further comprising a first sealing layer disposed on the circuit layer, covering the light emitting element layer, and including an inorganic insulating material,
wherein the first sealing layer is in contact with the auxiliary insulating layer in the hole peripheral area,
wherein the side surface of the main layer comprises:
a common bonding portion in contact with the second common layer;
a cathode bonding portion in contact with the cathode electrode; and
a sealing bonding portion in contact with the first sealing layer.

24. The display device of claim 19,
further comprising a touch sensor layer disposed on the first sealing layer,
wherein the touch sensor layer comprises:
a first additional overcoat layer disposed on the first sealing layer in each of the emission areas;
a first sensor electrode layer disposed on the first sealing layer in the non-emission area;
a first sensor insulating layer disposed on the first sensor electrode layer and the first additional overcoat layer;
a second sensor electrode layer disposed on the first sensor insulating layer;
an overcoat layer covering the second sensor electrode layer;
a second sensor insulating layer covering the overcoat layer; and
a second additional overcoat layer covering the second sensor insulating layer,
wherein the first additional overcoat layer is disposed between the sealing auxiliary units in the hole peripheral area, and
wherein the first sensor insulating layer is in contact with the first sealing layer on each of the cathode connection electrode and the sealing auxiliary units.

25. The display device of claim 19,
further comprising a touch sensor layer disposed on the first sealing layer,
wherein the touch sensor layer comprises:
a first additional overcoat layer evenly disposed on the first sealing layer in the display area;
an additional sensor insulating layer disposed on the first additional overcoat layer;
a first sensor electrode layer disposed on the additional sensor insulating layer;
a first sensor insulating layer disposed on the additional sensor insulating layer and the first sensor electrode layer;
a second sensor electrode layer disposed on the first sensor insulating layer;
an overcoat layer evenly covering the second sensor electrode layer; and
a second sensor insulating layer disposed on the overcoat layer,
wherein the additional sensor insulating layer is in contact with the first sealing layer in a portion adjacent to the edge of the hole area within the hole peripheral area.
